(19) United States
(12) Patent Application Publication
(10) Pub. No.: US 2019/0113811 A1
(43) Pub. Date: Apr. 18, 2019

(54) LIQUID CRYSTAL DISPLAY DEVICE

(71) Applicant: SHARP KABUSHIKI KAISHA, Sakai City, Osaka (JP)

(72) Inventors: YOSUKE IWATA, Sakai City (JP); MITSUHIRO MURATA, Sakai City (JP); TAKUMA TOMOTOSHI, Sakai City (JP); HIDEFUMI YOSHIDA, Sakai City (JP)

(73) Assignee: SHARP KABUSHIKI KAISHA, Sakai City, Osaka (JP)

(21) Appl. No.: 16/090,237

(22) PCT Filed: Mar. 22, 2017
(86) PCT No.: PCT/JP2017/011291

§ 371 Date: Sep. 29, 2018

(30) Foreign Application Priority Data
Mar. 29, 2016 (JP) 2016-066394

(51) Int. Cl. G02F 1/1337; G02F 1/1343; G02F 1/1362; G02F 1/1368; H01L 27/12

(52) U.S. Cl. CPC G02F 1/133784; G02F 1/133707; G02F 1/134363; H01L 27/124; G02F 1/136227; G02F 1/1368; G02F 1/136209

(57) ABSTRACT

The present invention provides a horizontal alignment mode liquid crystal display device capable of achieving high resolution, high speed response, and high transmittance. The liquid crystal display device of present invention sequentially includes a first substrate, a liquid crystal layer containing liquid crystal molecules, and a second substrate. The first substrate includes a first electrode, a second electrode provided closer to the liquid crystal layer than the first electrode is, and an insulating film provided between the first electrode and the second electrode. An opening portion (15) is formed in the second electrode in each of a plurality of units of display (50) arrayed in a matrix pattern. The liquid crystal molecules are aligned parallel to the first substrate in a voltage non-applied state in which no voltage is applied between the first electrode and the second electrode. The average slope of the contour of the opening portion in each of the units of display (50) is not zero, and the sign of the average slope differs from the signs of the average slopes of contours of opening portions in adjacent units of display.

### TECHNICAL FIELD

The present invention relates to a liquid crystal display device. More specifically, the present invention relates to a liquid crystal display device suitable for providing high-resolution pixels in a horizontal alignment mode.

### BACKGROUND ART

A liquid crystal display device is a display device that uses a liquid crystal composition for display. In a typical display method for this device, a voltage is applied to a liquid crystal composition sealed between a pair of substrates, and the alignment state of the liquid crystal molecules in the liquid crystal composition is changed in accordance with the applied voltage, whereby the light transmission amount is controlled. Such a liquid crystal display device is used in a wide range of fields by taking advantages such as thinness, lightweight, and low power consumption.

As a display method of a liquid crystal display device, a horizontal alignment mode in which control is performed by mainly rotating the alignment of liquid crystal molecules in a plane parallel to the substrate surface has attracted a great deal of attention because, for example, wide viewing angle characteristics can be easily obtained. For example, in recent years, liquid crystal display devices for smartphones and tablet PCs have widely used the in-plane switching (IPS) mode and the Fringe Field Switching (FFS) mode, each of which is one type of horizontal alignment mode.

With respect to such a horizontal alignment mode, research and development have been continued to improve the display quality by, for example, increasing the pixel resolution, improving the transmittance, and improving the response speed. As a technique for improving the response speed, for example, Patent Literature 1 discloses a liquid crystal display device using fringe electric fields, and a technique of providing a comb-tooth portion with a specific shape to a first electrode. In addition, Patent Literature 2 relates to an FFS mode liquid crystal display and discloses an electrode structure having a slit including two linear portions and a V-shaped portion formed by coupling the two linear portions in a V shape. According to this document, this technique can reduce defects caused by process variations and improve the display performance.

### CITATION LIST

### Patent Literature

### Patent Literature 1: JP 2015-114493 A

### Patent Literature 2: WO 2013/021929 A

### SUMMARY OF INVENTION

### Technical Problem

Although the horizontal alignment mode has an advantage of achieving a wide viewing angle, there is a problem that the response is slow as compared with the vertical alignment mode such as the multi-domain vertical alignment (MVA) mode. Although the response speed can be improved in the horizontal mode by using the technique disclosed in Patent Literature 1, the shape of the electrode is largely restricted by an ultra-high pixel resolution of 800 ppi or more. This makes it difficult to adopt a complicated electrode shape like that disclosed in Patent Literature 1. In addition, when a voltage is applied to the liquid crystal display device disclosed in Patent Literature 1, the liquid crystal molecules rotate in two or more azimuth directions within one pixel, so that boundaries (dark lines) between liquid crystal domains which do not transmit light are generated and the transmittance decreases.

According to Patent Literature 2, due to the influence of the V-shaped portion provided in the opening of the electrode, it is possible to improve the display performance such as transmittance by dividing the alignment of the liquid crystal molecules into two regions at the time of voltage application. However, the effect of speeding up is not great. In addition, there is still room for improvement in order to achieve further higher resolution and higher transmittance.

As a result of various studies, the present inventors have found that high speed can be achieved in an FFS mode liquid crystal display device even in the horizontal alignment mode by using the strain force generated by the bend-shaped and splay-shaped liquid crystal alignments formed in a narrow region by rotating liquid crystal molecules within a range smaller than a certain pitch at the time of voltage application to form four liquid crystal domains and rotating the liquid crystal molecules in the adjacent liquid crystal domains in mutually opposite azimuth directions.

FIG. 23 is a schematic plan view showing a counter electrode in an FFS mode liquid crystal display device according to Comparative Embodiment 1 studied by the present inventors. FIG. 24 is a plan view showing the alignment distribution simulation result of the liquid crystal molecules in the ON state in the liquid crystal display device according to Comparative Embodiment 1.

As shown in FIG. 23, in the FFS mode liquid crystal display device according to Comparative Embodiment 1, a counter electrode 14 having an opening portion 15 was disposed on the upper layer, and pixel electrodes (not shown) were disposed on the lower layer. The opening portion 15 was constituted by a longitudinal portion 16 and a pair of protruding portions 17 protruding to the opposite sides from the longitudinal portion 16, and had a shape symmetrical with respect to an initial alignment azimuth direction 22 of liquid crystal molecules 21. As shown in FIG. 24, in the FFS mode liquid crystal display device according to Comparative Embodiment 1, rotating the liquid crystal molecules 21 upon voltage application could form four liquid crystal domains in which the alignments of the liquid crystal molecules 21 were symmetrical with respect to each other, and the four liquid crystal domains could be stabilized by an oblique electric field at the pair of protruding portions 17, thereby improving the response characteristics.

However, in the liquid crystal display device according to Comparative Embodiment 1, because four liquid crystal domains are formed in one unit of display 50, crisscross dark lines as indicated by the portion surrounded by the dotted line in FIG. 24 are generated in the central portion of the unit of display 50, resulting in a decrease in transmittance. In addition, because the shape of the electrode is greatly restricted as the resolution becomes higher, it becomes difficult to generate four liquid crystal domains within one unit of display 50.

The present invention has been made in view of the above state of the art, and it is an object of the present invention to provide a horizontal alignment mode liquid crystal display device capable of achieving high resolution, high response speed, and high transmittance.

### Solution to Problem

As a result of extensive studies on a horizontal alignment mode liquid crystal display device capable of achieving high resolution, high response speed, and high transmittance, the present inventors focused attention on the relationship between the shape of each opening of an electrode used for forming fringe electric fields and the positions where dark lines were generated. It has been found that even if each opening of an electrode has a simple shape, making the shape of each opening of the electrode satisfy a specific condition in a plurality of units of display can rotate liquid crystal molecules in the same azimuth direction in the display regions of the respective units of display and rotate the liquid crystal molecules in different directions in the display regions of the adjacent units of display. This made it possible to form four liquid crystal domains in four units of display adjacent to each other vertically and horizontally and to overlap a crisscross dark line on a non-opening region between adjacent units of display. Accordingly, in a high resolution liquid crystal display device, it is possible to improve the response speed without reducing the transmittance, and the present inventors have satisfactorily achieved the above object, and have reached the present invention.

That is, one aspect of the present invention may be a liquid crystal display device sequentially including: a first substrate; a liquid crystal layer containing liquid crystal molecules; and a second substrate, wherein the first substrate includes a first electrode, a second electrode provided closer to the liquid crystal layer than the first electrode is, and an insulating film provided between the first electrode and the second electrode, an opening portion is formed in the second electrode in each of a plurality of units of display arrayed in a matrix pattern, the liquid crystal molecules are aligned parallel to the first substrate in a voltage non-applied state in which no voltage is applied between the first electrode and the second electrode, and the average slope of the contour of the opening portion in each of the units of display is not zero, and the sign of the average slope differs from the signs of the average slopes of contours of opening portions in adjacent units of display.

The liquid crystal molecules may have positive anisotropy of dielectric constant.

The first substrate may further include a source signal line and a gate signal line, and an initial alignment azimuth direction of the liquid crystal molecules may be parallel to a reference line of the opening portion which is the longer of a first straight line and a second straight line, the first line being longest among lines dividing the opening portion in the direction parallel to the source signal line or the gate signal line, the second straight line being longest among lines dividing the opening portion in the direction orthogonal to the first straight line.

The liquid crystal molecules may have negative anisotropy of dielectric constant.

The first substrate may further includes a source signal line and a gate signal line, and an initial alignment azimuth direction of the liquid crystal molecules is orthogonal to a reference line of the opening portion which is the longer of a first straight line and a second straight line, the first straight line being longest among lines dividing the opening portion in the direction parallel to the source signal line or the gate signal line, the second straight line being longest among lines dividing the opening portion in the direction orthogonal to the first straight line.

A shape of the opening portion in each of the units of display may be mirror-symmetrical with a shape of the opening portion in each adjacent unit of display.

In the second electrode, one or more slits may be formed as the opening portion for each of the units of display.

The opening portions in four display units adjacent to each other vertically and horizontally may form one shape.

The one shape may be an elliptic shape or oval shape.

The one shape may be a polygonal shape.

In a voltage applied state in which a voltage is applied between the first electrode and the second electrode, the liquid crystal molecules may be rotated in the same azimuth direction within a plane parallel to the first substrate in a display region of each of the units of display, and a rotational azimuth direction of the liquid crystal molecules in the display region of the unit of display may be opposite to a rotational azimuth direction of the liquid crystal molecules in a display region of each of the adjacent units of display.

### Advantageous Effects of Invention

The present invention can provide a horizontal alignment mode liquid crystal display device capable of achieving high resolution, high response speed, and high transmittance.

### BRIEF DESCRIPTION OF DRAWINGS

FIG. 1 is a schematic cross-sectional view of a liquid crystal display device according to Embodiment 1, showing an OFF state.

FIG. 2 is a view relating to the liquid crystal display device according to Embodiment 1, with (1) being a schematic plan view of Embodiment 1, and (2) being a view for explaining a reference line of an opening portion.

FIG. 3 is a view relating to the liquid crystal display device according to Embodiment 1, with (1) being a schematic plan view showing a counter electrode, and (2) being a view for explaining a method of obtaining the average slope of the contour of the opening portion.

FIG. 4 is a plan view showing the alignment distribution simulation result of the liquid crystal molecules in an ON state in the liquid crystal display device according to Embodiment 1.

FIG. 5 is a schematic cross-sectional view of a liquid crystal display device according to Embodiment 2, showing an OFF state.

FIG. 6 is a schematic plan view of the liquid crystal display device according to Embodiment 2, with (1) being a schematic plan view showing the elliptic opening formed by four units of display, and (2) being a schematic plan view showing the polygonal opening formed by four units of display.

FIG. 7 is a schematic plan view of a liquid crystal display device according to a comparative example, with (1) being a schematic plan view of Comparative Example 1, and (2) being a schematic plan view of Comparative Example 2.

FIG. 8 is a view relating to a liquid crystal display device according to Example 1, with (1) being a schematic plan view showing a counter electrode and pixel electrodes, (2) being a plan view showing the alignment distribution simulation result of liquid crystal molecules when 4.5 V is applied, (3) being a schematic plan view of a counter electrode and pixel electrodes, and (4) being a view showing an electric field distribution in the region in (3) at the time of voltage application.

FIG. 9 is a view relating to a liquid crystal display device according to Comparative Example 1, with (1) being a schematic plan view showing a counter electrode and pixel electrodes, and (2) being a plan view showing alignment distribution simulation result of liquid crystal molecules upon application of a voltage of 4.5 V.

FIG. 10 is a view relating to a liquid crystal display device according to Comparative Example 2, with (1) being a schematic plan view showing a counter electrode and pixel electrodes, and (2) being a plan view showing the alignment distribution simulation result of liquid crystal molecules upon application of a voltage of 4.5 V.

FIG. 11 is a graph showing the response characteristics of the liquid crystal display devices according to Example 1 and Comparative Examples 1 and 2, with (1) being a graph showing a rise response characteristic, and (2) being a graph showing a decay response characteristic.

FIG. 12 is a graph obtained by plotting the response time ratios between the liquid crystal display devices according to Examples 1 to 5 and Comparative Examples 1, 3, 5, 7, and 9 as a function of resolution.

FIG. 13 is a schematic plan view of a liquid crystal display device according to Example 6.

FIG. 14 is a schematic cross-sectional view of the liquid crystal display device according to Example 6, showing an OFF state.

FIG. 15 is a schematic plan view of a liquid crystal display device according to a comparative example, with (1) being a schematic plan view of Comparative Example 11, and (2) being a schematic plan view of Comparative Example 12.

FIG. 16 is a view relating to a liquid crystal display device according to Example 6, with (1) being a schematic plan view showing a counter electrode and pixel electrodes, and (2) being a plan view showing the alignment distribution simulation result of liquid crystal molecules upon application of a voltage of 6.0 V.

FIG. 17 is a view relating to a liquid crystal display device according to Comparative Example 11, with (1) being a schematic plan view showing a counter electrode and pixel electrodes, and (2) being a plan view showing the alignment distribution simulation result of liquid crystal molecules upon application of a voltage of 6.0 V.

FIG. 18 is a view relating to a liquid crystal display device according to Comparative Example 12, with (1) being a schematic plan view showing a counter electrode and pixel electrodes, and (2) being a plan view showing the alignment distribution simulation result of liquid crystal molecules upon application of a voltage of 6.0 V.

FIG. 19 is a view relating to a liquid crystal display device according to Example 7, with (1) being a schematic plan view showing a counter electrode and pixel electrodes, and (2) being a plan view showing the alignment distribution simulation result of liquid crystal molecules upon application of a voltage of 4.5 V.

FIG. 20 is a view relating to a liquid crystal display device according to Example 8, with (1) being a schematic plan view showing a counter electrode and pixel electrodes, and (2) being a plan view showing the alignment distribution simulation result of liquid crystal molecules upon application of a voltage of 4.5 V.

FIG. 21 is a view relating to a liquid crystal display device according to Example 7, with (1) being a schematic plan view of the liquid crystal display device, (2) being a schematic plan view showing a counter electrode and pixel electrodes, and (3) being a view showing an electric field distribution in the region in (2) at the time of voltage application.

FIG. 22 is a view relating to a liquid crystal display device according to Example 9, with (1) being a schematic plan view showing a counter electrode and pixel electrodes, and (2) being a plan view showing the alignment distribution simulation result of liquid crystal molecules upon application of a voltage of 4.5 V.

FIG. 23 is a schematic plan view showing a counter electrode in an FFS mode liquid crystal display device according to Comparative Embodiment 1 studied by the present inventors.

FIG. 24 is a plan view showing the alignment distribution simulation result of the liquid crystal molecules in the ON state in the liquid crystal display device according to Comparative Embodiment 1.

### DESCRIPTION OF EMBODIMENTS

Embodiments of the present invention will be described below. The present invention is not limited to the following embodiments, and it is possible to appropriately change the design within the scope in which the configuration of the present invention is satisfied.

In the following description, the same reference numerals denote the same parts or parts having similar functions in different drawings, and a repetitive description thereof is omitted.

The configurations described in the embodiments may be appropriately combined or changed within a range not deviating from the gist of the present invention.

### Embodiment 1

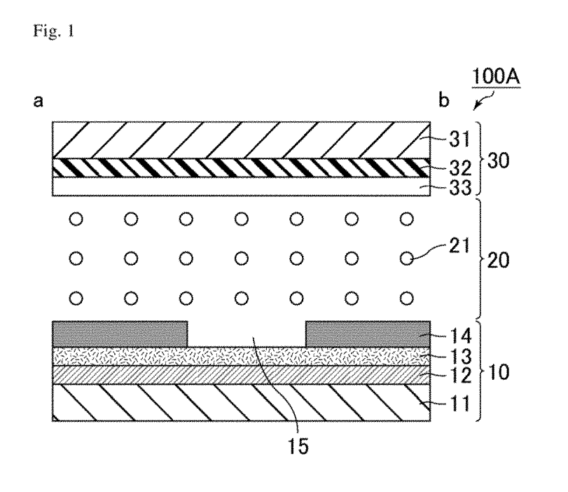

A liquid crystal display device according to Embodiment 1 will be described with reference to FIGS. 1 to 4.

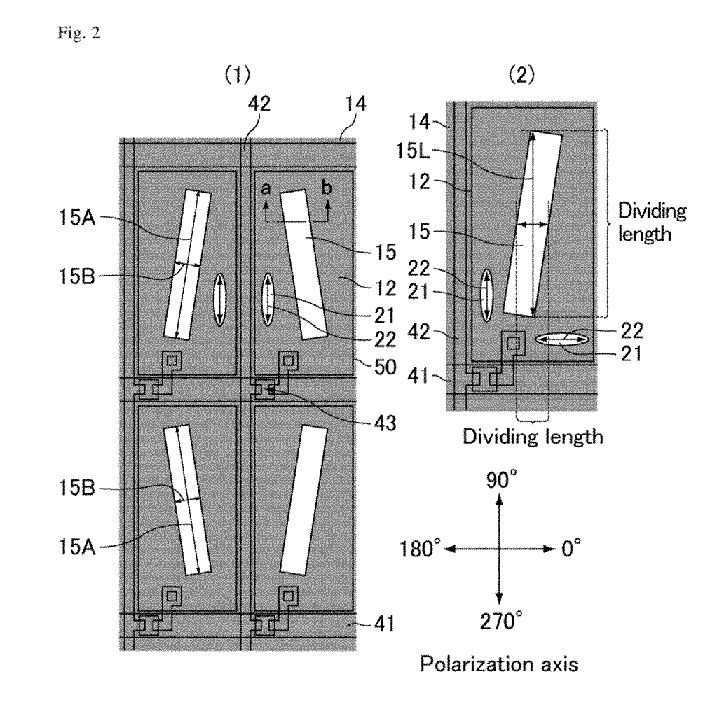

FIG. 1 is a schematic cross-sectional view of the liquid crystal display device according to Embodiment 1, showing an OFF state. FIG. 1 shows a section taken along line a-b shown in FIG. 2.

As shown in FIG. 1, a liquid crystal display device 100A according to Embodiment 1 sequentially includes a first substrate 10, a liquid crystal layer 20 containing liquid crystal molecules 21, and a second substrate 30. The first substrate 10 is a TFT array substrate, and has a structure formed by sequentially stacking a first polarizer (not shown), an insulating substrate (for example, a glass substrate) 11, a pixel electrode (a first electrode) 12, an insulating layer (insulating film) 13, and a counter electrode (second electrode) 14 toward the liquid crystal layer 20. The second substrate 30 is a color filter substrate, and has a structure formed by sequentially stacking a second polarizer (not shown), an insulating substrate (for example, a glass substrate) 31, a color filter 32, and an overcoat layer 33 toward the liquid crystal layer 20. Both the first polarizer and the second polarizer are absorptive polarizers, and have a crossed Nicols configuration relationship with their polarization axes being orthogonal to each other.

The pixel electrode 12 is a planar electrode on which no opening is formed. The pixel electrode 12 and the counter electrode 14 are stacked with the insulating layer 13 being interposed between them, and the pixel electrode 12 exists below an opening portion 15 provided in the counter electrode 14. Thus, when a potential difference is generated between the pixel electrode 12 and the counter electrode 14, a fringe-like electric field is generated around the opening portion 15 of the counter electrode 14.

The counter electrode 14 supplies a potential common to each unit of display. Thus, the counter electrode 14 may be formed on almost the entire surface of the first substrate 10 (excluding the opening portion for forming a fringe electric field). The counter electrode 14 may be electrically connected to the external connection terminal at the outer peripheral portion (frame region) of the first substrate 10.

As the insulating layer 13 provided between the pixel electrode 12 and the counter electrode 14, for example, an organic film (dielectric constant ε=3 to 4), an inorganic film (dielectric constant ε=5 to 7) such as silicon nitride (SiNx), silicon oxide (SiO₂), or a stacked film of them can be used.

The liquid crystal molecules 21 may have negative anisotropy of dielectric constant (Δε) defined by the following formula, which may have a negative or positive value. That is, the liquid crystal molecules 21 may have negative anisotropy of dielectric constant or positive anisotropy of dielectric constant. The liquid crystal material including the liquid crystal molecules 21 having negative anisotropy of dielectric constant tends to have a relatively high viscosity. Thus, from the viewpoint of obtaining high-speed response performance, a liquid crystal material containing the liquid crystal molecules 21 having positive anisotropy of dielectric constant is preferable. However, even with a liquid crystal material having negative anisotropy of dielectric constant, because it has a viscosity as low as that of a liquid crystal material having positive anisotropy of dielectric constant, the same high speed response performance can be obtained by the means of this embodiment.

Δε=(dielectric constant in major axis direction)−(dielectric constant in minor axis direction)

The alignment of liquid crystal molecules 21 in a voltage non-applied state (to be also simply referred to as “no voltage applied state” or “OFF state” hereinafter) in which no voltage is applied between the pixel electrode 12 and the counter electrode 14 is controlled to be parallel to the first substrate 10. Being “parallel” includes not only being perfectly parallel but also being regarded as parallel (substantially parallel) in this technical field. The pre-tilt angle (tilt angle in the OFF state) of the liquid crystal molecules 21 is preferably less than 3° with respect to the surface of the first substrate 10, more preferably less than 1°.

In a voltage applied state (to be also simply referred to as “voltage applied state” or “ON state” hereinafter) in which a voltage is applied between the pixel electrode 12 and the counter electrode 14, a voltage is applied to the liquid crystal layer 20, and the alignment of liquid crystal molecules 21 is controlled by the multilayer structure constituted by the pixel electrode 12, the insulating layer 13, and the counter electrode 14 which are provided on the first substrate 10. In this case, the pixel electrode 12 is an electrode provided for each unit of display, and the counter electrode 14 is an electrode shared by a plurality of units of display. Note that “unit of display” means a region corresponding to one pixel electrode 12 and may be referred to as a “pixel” in the technical field of liquid crystal display devices. When one pixel is divisionally driven, each element may be referred to as a “sub-pixel”, “dot”, or “picture element”.

The second substrate 30 is not particularly limited, and a color filter substrate generally used in the field of liquid crystal display devices can be used. The overcoat layer 33 flattens the surface of the second substrate 30 which is located on the liquid crystal layer 20 side, and for example, an organic film (dielectric constant ε=3 to 4) can be used.

Usually, the first substrate 10 and the second substrate 30 are bonded together with a sealing material provided so as to surround the liquid crystal layer 20, and the liquid crystal layer 20 is held by the first substrate 10, the second substrate 30, and the sealing material in a predetermined region. As a sealant, for example, an epoxy resin containing an inorganic filler or an organic filler and a hardening agent can be used.

In addition to the first substrate 10, the liquid crystal layer 20, and the second substrate 30, the liquid crystal display device 100A may include a backlight, an optical film such as a retardation film, a viewing angle expansion film, or a brightness enhancement film, an external circuit such as a tape carrier package (TCP) or a printed circuit board (PCB), and a member such as a bezel (frame). These members are not particularly limited, and because those commonly used in the field of liquid crystal display devices can be used, descriptions of them will be omitted.

The alignment mode of the liquid crystal display device 100A is a fringe field switching (FFS) mode.

Although not shown in FIG. 1, a horizontal alignment film is usually provided on the surface of the first substrate 10 and/or the second substrate 30 which is located on the liquid crystal layer 20 side. The horizontal alignment film has a function of aligning the liquid crystal molecules 21 existing near the film in parallel to the film surface. Furthermore, the horizontal alignment film can align the major axis directions of the liquid crystal molecules 21, aligned parallel to the first substrate 10, in a specific in-plane azimuth direction. It is preferable that the horizontal alignment film has been subjected to alignment treatment such as photo alignment treatment and rubbing treatment. The horizontal alignment film may be a film made of an inorganic material or a film made of an organic material.

The positions of the counter electrode 14 and the pixel electrode 12 may be interchanged. That is, in the multilayer structure shown in FIG. 1, the counter electrode 14 is adjacent to the liquid crystal layer 20 through a horizontal alignment film (not shown), but the pixel electrode 12 may be provided adjacent to the layer 20 through a horizontal alignment film (not shown). In this case, the opening portion 15 is formed in the pixel electrode 12 instead of the counter electrode 14. In addition, the counter electrode 14 corresponds to the first electrode, and the pixel electrode 12 corresponds to the second electrode.

FIG. 2 is a view relating to the liquid crystal display device according to Embodiment 1, with (1) being a schematic plan view of Embodiment 1, and (2) being a view for explaining a reference line of an opening portion. As shown in FIG. 2(1), a plurality of units of display 50 are arrayed in a matrix pattern in the display region of the liquid crystal display device 100A, and in a plan view, each opening portion 15 is formed so as to overlap the corresponding pixel electrode 12, and is shaped such that the average slope of the contour satisfies a specific condition described later. These opening portions 15 are used to form a fringe electric field (oblique electric field). The opening portions 15 are preferably arranged for each unit of display 50, and are preferably arranged with respect to all units of display 50. The planar shape of each unit of display 50 is not particularly limited, and can include quadrilaterals such as a rectangle and a square.

In a plan view, the initial alignment azimuth direction 22 of the liquid crystal molecules 21 is parallel to the polarization axis of one of the first polarizer and the second polarizer, and is perpendicular to the other polarization axis. Therefore, the control method of the liquid crystal display device 100A is a so-called normally black mode in which black display is performed in a voltage non-applied state where no voltage is applied to the liquid crystal layer 20.

A reference line 15L of the opening portion 15 will be described with reference to FIG. 2(2). Assume that a straight line parallel to one of a source signal line 42 (signal conductive line) and a gate signal line 41 (scanning conductive line) and having the longest length (dividing length) dividing the opening portion 15 is defined as a first straight line, and a straight line orthogonal to the first straight line and having the longest length (dividing length) dividing the opening portion 15 is defined as a second straight line. In this case, the longer of the first and second straight lines is defined as the reference line 15L of the opening portion 15. Therefore, in the example shown in FIG. 2(2), a straight line parallel to the source signal line 42 (signal conductive line) is the reference line 15L of the opening portion 15. Note that when the opening portion 15 is provided up to the end of the unit of display 50 (the boundary with the adjacent unit of display 50), the length that divides the opening portion 15 having an end of the unit of display 50 as one end is measured. Further, the first straight line may be parallel to any of the gate signal line 41 (scanning conductive line) and the gate signal line 41 (scanning conductive line). Assume that the gate signal line 41 and the source signal line 42 are orthogonal to each other. In this case, regardless of whether a target parallel to the first straight line is the gate signal line 41 or the source signal line 42, the same result, that is, the reference line 15L of the opening portion 15, can be obtained.

When the liquid crystal molecules 21 having positive anisotropy of dielectric constant (see the liquid crystal molecules 21 on the left side in FIG. 2(2)) are used, the initial alignment azimuth direction 22 of the liquid crystal molecules 21 and the reference line 15L of the opening portion 15 are preferably parallel to each other. The liquid crystal molecules 21 having positive anisotropy of dielectric constant rotate so as to be orthogonal to the slope of the contour of the opening portion 15 when a voltage is applied. The angle (acute angle portion) formed between an azimuth direction orthogonal to the slope of the contour of the opening portion 15 and the initial alignment azimuth direction 22 of the liquid crystal molecule 21 increases when the initial alignment azimuth direction 22 of the liquid crystal molecules 21 is parallel to the reference line 15L of the opening portion 15 as compared with when the initial alignment azimuth direction 22 of the liquid crystal molecules 21 is orthogonal to the reference line 15L of the opening portion 15. For this reason, when the liquid crystal molecules 21 having positive anisotropy of dielectric constant are used, it is possible to more largely rotate the liquid crystal molecules 21 from the initial alignment azimuth direction 22 at the time of voltage application and more improve the transmittance when the initial alignment azimuth direction 22 of the liquid crystal molecules 21 is parallel to the reference line 15L of the opening portion 15.

When the liquid crystal molecules 21 having negative anisotropy of dielectric constant (see the liquid crystal molecules 21 on the right side in FIG. 2(2)) are used, the initial alignment azimuth direction 22 of the liquid crystal molecules 21 and the reference line 15L of the opening portion 15 are preferably orthogonal to each other. The liquid crystal molecules 21 having negative anisotropy of dielectric constant rotate so as to become parallel to the slope of the contour of the opening portion 15 at the time of voltage application. The angle (acute angle portion) formed between an azimuth direction parallel to the slope of the contour of the opening portion 15 and the initial alignment azimuth direction 22 of the liquid crystal molecule 21 increases when the initial alignment azimuth direction 22 of the liquid crystal molecules 21 is orthogonal to the reference line 15L of the opening portion 15 as compared with when the initial alignment azimuth direction 22 of the liquid crystal molecules 21 is parallel to the reference line 15L of the opening portion 15. For this reason, when the liquid crystal molecules 21 having negative anisotropy of dielectric constant are used, it is possible to more largely rotate the liquid crystal molecules 21 from the initial alignment azimuth direction 22 at the time of voltage application and more improve the transmittance when the initial alignment azimuth direction 22 of the liquid crystal molecules 21 is orthogonal to the reference line 15L of the opening portion 15.

In this specification, the initial alignment azimuth direction of liquid crystal molecules means the alignment direction of liquid crystal molecules in a voltage non-applied state in which no voltage is applied between the first electrode and the second electrode, that is, between the pixel electrode and the counter electrode. The alignment azimuth direction of liquid crystal molecules means the major-axis direction of the liquid crystal molecules.

Although FIG. 2(1) shows a case where the liquid crystal molecules 21 have positive anisotropy of dielectric constant, the initial alignment azimuth direction 22 of the liquid crystal molecules 21 having negative anisotropy of dielectric constant is rotated by 90° with respect to the initial alignment azimuth direction 22 of the liquid crystal molecules 21 having positive anisotropy of dielectric constant.

As shown in FIG. 2, the drain of a TFT 43 is electrically connected to each pixel electrode 12. A gate signal line (scanning conductive line) 41 is electrically connected to the gate of the TFT 43, and a source signal line (signal conductive line) 42 is electrically connected to the source of the TFT 43. Accordingly, ON/OFF control of the TFT 43 is performed in accordance with the scanning signal input to the gate signal line 41. Then, when the TFT 43 is on, the data signal (source voltage) input to the source signal line 42 is supplied to the pixel electrode 12 via the TFT 43. In this way, in the voltage applied state, a source voltage is applied to the pixel electrode 12 on the lower layer via the TFT 43, and a fringe electric field is generated between the counter electrode 14 and the pixel electrode 12 formed on the upper layer via the insulating film 13. As the TFT 43, a transistor having a channel formed with indium-gallium-zinc-oxygen (IGZO) which is an oxide semiconductor is suitably used.

As shown in FIG. 2(1), it is preferable that the opening portions 15 of the counter electrode 14 are arranged side by side in the row direction and/or the column direction between adjacent units of display 50. This makes it possible to stabilize the alignment of the liquid crystal molecules 21 in the voltage applied state. Assume that in the adjacent units of display 50, the opening portions 15 are alternately arranged in a staggered lattice pattern in the row direction or the column direction as in the case where in a certain unit of display 50, the opening portions 15 are formed on one side in the longitudinal direction of the unit of display 50, while in the adjacent unit of display 50, the opening portions 15 are formed on the other side in the longitudinal direction. In this case, the alignment of the liquid crystal molecules 21 becomes unstable and the transmittance and the response speed decrease sometimes.

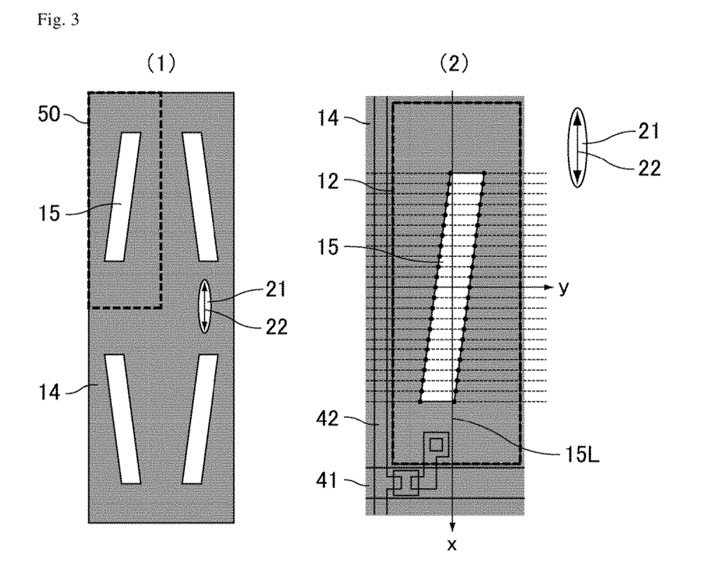

FIG. 3 is a view relating to the liquid crystal display device according to Embodiment 1, with (1) being a schematic plan view showing a counter electrode, and (2) being a view for explaining a method of obtaining the average slope of the contour of the opening portion. The opening portion 15 is provided to generate a fringe electric field between the counter electrode 14 and the pixel electrode 12. Then, the average slope of the contour of the opening portions 15 in each unit of display 50 is not zero (condition 1), and the sign of the average slope differs from the signs of the average slopes of the contours of the opening portions 15 in the adjacent units of display 50 (condition 2).

In this specification, the average slope of the contour of the opening portion 15 in each unit of display 50 is obtained as follows.

As shown in FIG. 3(2), assume that the reference line 15L (any reference line can be assumed if a plurality of reference lines can be assumed) of the opening portion 15 is defined as the x-axis, and one of the first straight line and the second straight line which does not correspond to the reference line 15L of the opening portion 15 (any straight line can be assumed if a plurality of straight lines can be assumed) is defined as the y-axis. N straight lines parallel to the y-axis are drawn to equally divide the length of the opening portion 15 projected on the x-axis into (n−1) portions, and a slope at each of the intersection points between the straight lines and the contour of the opening portion 15 is obtained by differentiation. The value obtained by dividing the sum of the slopes by the total number of intersection points is taken as the average slope of the contour of the opening portion 15. When there are a plurality of intersection points as they form one straight line, it is assumed that differentiation is performed at all the intersection points.

However, the point where the slope becomes 0 or infinite does not contribute to alignment control and hence is excluded. Note that the n straight lines parallel to the y-axis also include a straight line passing through the two end portions of the opening portion 15 projected on the x-axis. That is, the n straight lines parallel to the y-axis include a straight line passing through the two points farthest from each other in the x-axis direction of the opening portion 15 (at least one of which may be a line). The positive and negative directions of the x-axis and the y-axis can be arbitrarily determined with the intersection point between the x-axis and the y-axis being the origin. The contour of the opening portion 15 in each unit of display 50 is a boundary line between the opening portion 15 and the counter electrode 14 and is not a boundary line between the opening portions 15 of the adjacent units of display 50 like Embodiment 2 to be described later.

Although n is an arbitrary positive integer and ideally infinite, n is preferably an integer of 100 to 300, preferably an integer of 200 to 300. Further, condition 1 and condition 2 described above may be satisfied for all n in these numerical ranges.

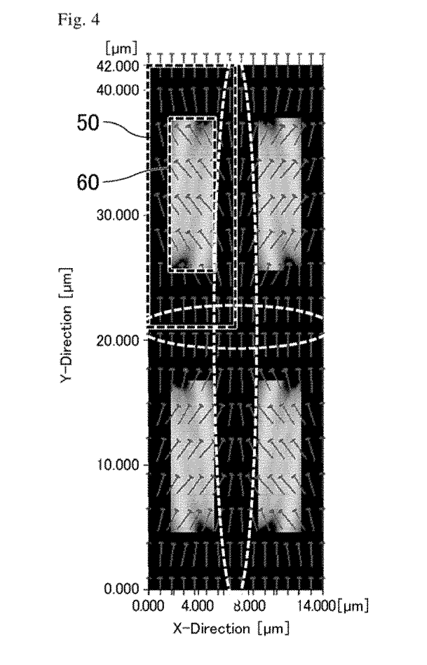

FIG. 4 is a plan view showing the alignment distribution simulation result of the liquid crystal molecules in the ON state in the liquid crystal display device according to Embodiment 1. Even if the opening portion 15 has a simple shape, the average slope of the contour of the opening portion 15 in each unit of display 50 is not zero, and the sign of the average slope differs from the signs of the average slopes of the contours of the opening portions 15 in the adjacent units of display 50. As shown in FIG. 4, this makes it possible to rotate the liquid crystal molecules 21 in a display region 60 of one unit of display 50 in the same azimuth direction and to rotate the liquid crystal molecules 21 in the display regions 60 of the adjacent units of display 50 in different directions. As a result, it is possible to form four liquid crystal domains in which the alignments of the liquid crystal molecules 21 are symmetrical with respect to each other between the four units of display 50 adjacent to each other vertically and horizontally, so that a crisscross dark line can be made to overlap the non-opening region which transmits no light between the display regions 60 instead of the display region (light-transmitting portion) 60 that transmits light. This makes it possible to suppress a reduction in transmittance due to the dark line. In addition, bend-shaped or splay-shaped liquid crystal alignments can be formed in two adjacent liquid crystal domains, so that high-speed response can be achieved. As a result, even when the liquid crystal display device 100A includes high-resolution pixels, it is possible to suppress a reduction in transmittance and to improve the response speed. The resolution of the liquid crystal display device 100A is preferably 600 ppi or more, more preferably 800 ppi or more, and still more preferably 1000 ppi or more. The display region 60 of the unit of display 50 may be referred to as an opening region.

From the viewpoint of overlapping a crisscross dark line on a non-opening region and further improving the transmittance while more reliably generating four liquid crystal domains in four units of display adjacent to each other vertically and horizontally, in a voltage applied state in which a voltage is applied between the pixel electrode 12 and the counter electrode 14, the liquid crystal molecules 21 preferably rotate in the same azimuth direction within a plane parallel to the first substrate 10 in the display region 60 of each unit of display 50, and the rotational azimuth direction of the liquid crystal molecules 21 in the display region 60 of each unit of display 50 is preferably opposite to the rotational azimuth direction of the liquid crystal molecules 21 in the display region 60 of the adjacent unit of display 50.

In this specification, the rotation of the liquid crystal molecules 21 in the same azimuth direction means that the liquid crystal molecules 21 rotate to the same side with respect to the initial alignment azimuth direction 22. That the liquid crystal molecules 21 in a certain region (for example, the display region 60 of the unit of display 50) rotate in the same azimuth direction means that the liquid crystal molecules 21 in the region may rotate in substantially the same azimuth direction, and not all the liquid crystal molecules 21 in the region need not rotate in the same azimuth direction and most of the rotating liquid crystal molecules 21 in the region may rotate in the same azimuth direction. Specifically, it is preferable that 80% or more of the rotating liquid crystal molecules in the region (the display region 60 of each unit of display 50) rotate in the same azimuth direction.

In this specification, that the liquid crystal molecules 21 rotate in the opposite azimuth direction means that the liquid crystal molecules 21 rotate to the opposite side with respect to the initial alignment azimuth direction 22. That the liquid crystal molecules 21 in a certain region (for example, the display region 60 of the unit of display 50) rotate in the opposite azimuth direction to the rotational azimuth direction of the liquid crystal molecules 21 in the adjacent region (for example, the display region 60 of the unit of display 50) means that the liquid crystal molecules 21 in the region rotate in substantially the opposite azimuth direction to the rotational azimuth direction of the liquid crystal molecules 21 in the adjacent region and not all the liquid crystal molecules 21 in the region need not necessarily rotate in the opposite azimuth direction to the rotational azimuth direction of all the liquid crystal molecules 21. Specifically, it is preferable that the rotational azimuth direction of 80% or more of the rotating liquid crystal molecules 21 in the region (the display region 60 of each unit of display 50) is opposite to the rotational azimuth direction of 80% or more of the rotating liquid crystal molecules 21 in the adjacent region (the display region 60 of the unit of display 50).

Further, in this specification, the liquid crystal domain means a region defined by a boundary (dark line) at which the liquid crystal molecules 21 do not rotate from the initial alignment azimuth direction 22 at the time of voltage application. Among the four regions adjacent to each other vertically and horizontally, in the liquid crystal domains in the left and right regions, the liquid crystal molecules 21 rotate in the opposite azimuth direction. Further, in this specification, “vertically and horizontally” refer to the relative positional relationship of four targets (for example, units of display 50 or regions), and do not mean absolute directions.

As described above, in order to rotate the liquid crystal molecules 21 in the display region 60 of the unit of display 50 in the same azimuth direction, the azimuth direction in which a fringe electric field is generated may be tilted to rotate the liquid crystal molecules 21 in the azimuth direction. That is, the shape of the opening portion 15 may be determined so that a fringe electric field is generated in a desired azimuth direction. In this case, it is not necessary that the entire contour of the opening portion 15 has a desired azimuth direction, and it is only necessary that the average slope of the contour of the opening portion 15 is not zero. This makes it possible to rotate the liquid crystal molecules 21 in the display region 60 of the unit of display 50 in the same azimuth direction.

The absolute value of the average slope of the contour of the opening portion 15 is preferably 0.05 to 2, more preferably 0.06 to 1.5, and even more preferably 0.07 to 1. When the average absolute value of the slopes of the contour of the opening portion 15 is in the above range, the alignment state of the liquid crystal molecules 21 in the display region 60 of the unit of display 50 can be more reliably controlled, thus further improving the transmittance.

The opening portion 15 preferably has a longitudinal shape. As shown in FIG. 2(1), the opening portion 15 having a longitudinal shape is the opening portion 15 formed in a longitudinal shape having a length longer in the longitudinal direction 15A than a width in the transverse direction 15B, and the longitudinal shape is, for example, an ellipse, a shape similar to an ellipse such as an egg shape, an oval shape, a shape similar to an oval shape, a longitudinal polygon such as a parallelogram having different lengths of two adjacent sides (for example, a rectangle), a shape similar to a longitudinal polygon, a shape having at least one corner of a longitudinal polygon rounded, a shape obtained by dividing each of these shapes symmetrically in the longitudinal direction and the transverse direction into four, and the like. Making the opening portion 15 have such a simple shape allows the liquid crystal display device 100A to have a higher resolution.

The shape of the opening portion 15 in each of the units of display 50 may be mirror-symmetrical with the shape of the opening portion 15 in each adjacent unit of display 50. Providing the opening portion 15 having such a shape can implement a desired alignment more efficiently. Note that “mirror symmetry” means that when a boundary line between two units of display 50 adjacent to each other vertically or horizontally is taken as an axis of symmetry and one unit of display 50 is folded back on the axis of symmetry as a boundary, 75% of one opening portion 15 overlaps the other opening portion 15.

In the counter electrode 14, one or more slits may be formed as the opening portion 15 for each unit of display 50. When a plurality of slits are formed for each unit of display 50, the average slope of the contour of the opening portion 15 in each unit of display 50 is calculated by averaging the slopes of the respective slits and then dividing the sum of the average slopes by the total number of slits.

The operation of the liquid crystal display device 100A will be described below.

No electric field is formed in the liquid crystal layer 20 in the OFF state, and the liquid crystal molecules 21 are aligned parallel to the first substrate 10. Since the alignment azimuth direction of the liquid crystal molecules 21 is parallel to the polarization axis of one of the first polarizer and the second polarizer and the first polarizer and the second polarizer are in a crossed Nicols configuration relationship, the liquid crystal display device 100A in the OFF state transmits no light and performs black display.

In the ON state, an electric field corresponding to the magnitude of the voltage between the pixel electrode 12 and the counter electrode 14 is formed in the liquid crystal layer 20. Specifically, because the opening portion 15 is formed in the counter electrode 14 provided closer to the liquid crystal layer 20 than the pixel electrode 12, a fringe electric field is generated around the opening portion 15. The liquid crystal molecules 21 rotate under the influence of the electric field, and change the alignment azimuth direction from the alignment azimuth direction in the OFF state to the alignment azimuth direction in the ON state. As a result, the liquid crystal display device 100A in the ON state transmits light and performs white display.

### Embodiment 2

A liquid crystal display device according to Embodiment 2 has the same configuration as that of the liquid crystal display device 100A according to Embodiment 1 except for the shape of an opening portion 15 provided in a counter electrode 14. Therefore, in this embodiment, characteristics unique to the embodiment will mainly be described, and a description overlapping Embodiment 1 will be omitted as appropriate.

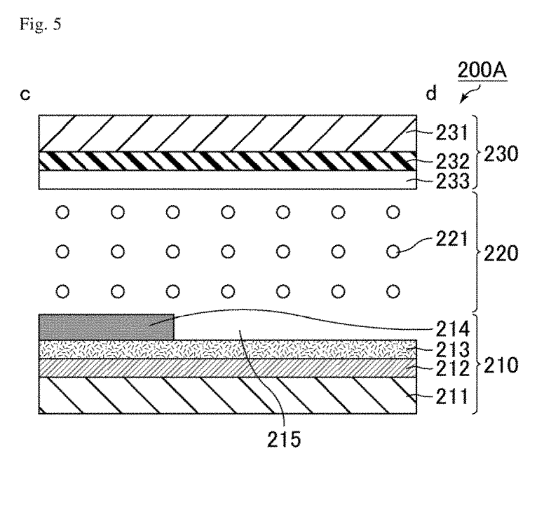

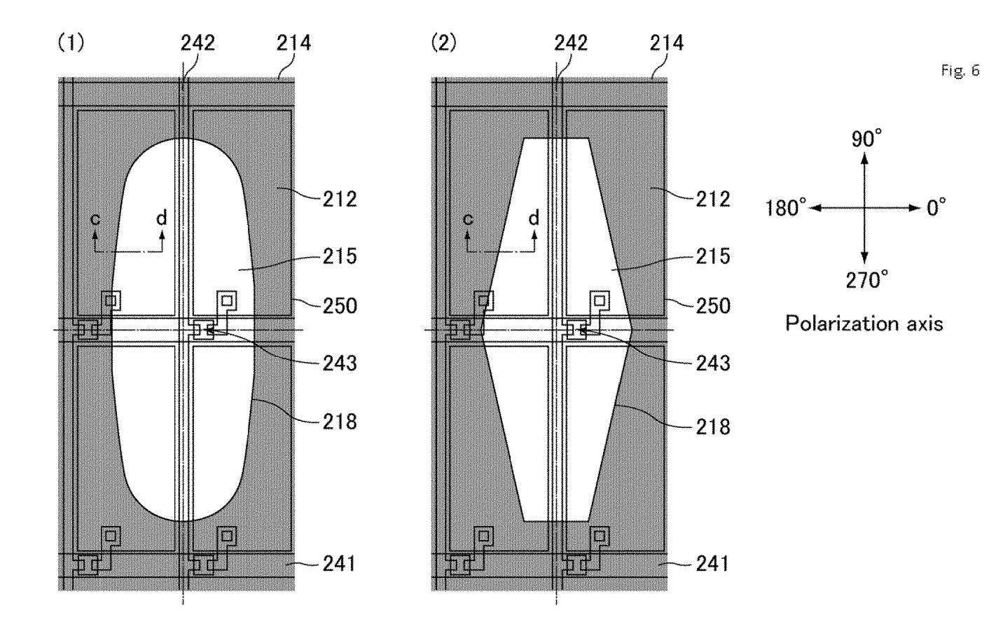

The liquid crystal display device according to Embodiment 2 will be described with reference to FIGS. 5 and 6. FIG. 5 is a schematic cross-sectional view of the liquid crystal display device according to Embodiment 2, showing an OFF state. FIG. 5 shows a section taken along line c-d shown in FIG. 6.

As shown in FIG. 5, a liquid crystal display device 200A according to Embodiment 2 sequentially includes a first substrate 210, a liquid crystal layer 220 containing liquid crystal molecules 221, and a second substrate 230. The first substrate 210 is a TFT array substrate, and has a structure formed by sequentially stacking a first polarizer (not shown), an insulating substrate (for example, a glass substrate) 211, a pixel electrode (a first electrode) 212, an insulating layer (insulating film) 213, and a counter electrode (second electrode) 214 toward the liquid crystal layer 220. The counter electrode 214 is provided with an opening portion 215. The second substrate 230 is a color filter substrate, and has a structure formed by sequentially stacking a second polarizer (not shown), an insulating substrate (for example, a glass substrate) 231, a color filter 232, and an overcoat layer 233 toward the liquid crystal layer 220. Both the first polarizer and the second polarizer are absorptive polarizers, and have a crossed Nicols configuration relationship with their polarization axes being orthogonal to each other.

FIG. 6 is a schematic plan view of the liquid crystal display device according to Embodiment 2, with (1) being a schematic plan view showing the elliptic opening formed by four units of display, and (2) being a schematic plan view showing the polygonal opening formed by four units of display. As shown in FIG. 6, a plurality of units of display 250 are arranged in a matrix pattern in the drive display region (active area) of the liquid crystal display device 200A, and the opening portion 215 is provided in correspondence with each unit of display 250. Four opening portions 215 in the four units of display 250 adjacent to each other vertically and horizontally form one large opening 218, which is arranged across the four units of display 250 adjacent to each other vertically and horizontally. In a plan view, each opening portion 215 is formed so as to overlap the corresponding pixel electrode 212, and is shaped such that the average slope of the contour satisfies the conditions 1 and 2 described above. These opening portions 215 are used to form a fringe electric field (oblique electric field). The opening portions 215 are preferably arranged for each unit of display 250, and are preferably arranged with respect to all units of display 250.

As shown in FIG. 6, the drain of a TFT 243 is electrically connected to each pixel electrode 212 as in Embodiment 1. A gate signal line 241 is electrically connected to the gate of the TFT 243, and a source signal line 242 is electrically connected to the source of the TFT 243.

The shape of the opening portion 215 in Embodiment 2 will be further described. As shown in FIG. 6, in the liquid crystal display device 200A according to Embodiment 2, in the plurality of units of display 250 arrayed in a matrix pattern, the opening portions 215 in the four units of display 250 adjacent to each other vertically and laterally form one shape (opening 218). Forming such a shape makes it possible to more easily achieve a higher resolution. Note that in this case, the contour of the opening portion 215 in each unit of display 250 is a boundary line between the opening portion 215 and the counter electrode (second electrode) 214 and is not a boundary line between the opening portions 215 of the adjacent units of display 250. Therefore, as described above, in this embodiment, in calculating the average slope of the contour of the opening portion 215 in each unit of display 250, no consideration is given to the boundary line between the opening portions 215 in the adjacent units of display 250.

When the opening portions 215 in the four units of display 250 adjacent to each other vertically and horizontally form one shape (opening 218), the one shape may be an elliptic shape or oval shape. This makes it possible to more easily implement a desired alignment. Note that the elliptic shape is preferably an ellipse, but from the viewpoint of the effect of the present invention, the shape may be the one that can be regarded as an ellipse (substantial ellipse), for example, an ellipse partly having irregularities, a shape similar to an ellipse such as an egg shape, or a polygon that can be substantially regarded as an ellipse. The oval shape is preferably an oval, but from the viewpoint of the effect of the present invention, the shape may be the one that can be regarded as an oval (substantial oval), for example, an oval partly having irregularities, or a polygon that can be substantially regarded as an oval.

When the opening portions 215 in the four units of display 250 adjacent to each other vertically and horizontally form one shape (opening 218), the one shape may be a polygonal shape. This also makes it possible to more easily implement a desired alignment. The polygonal shape is an m-polygon (m is an integer of 4 or more; the same applies hereinafter), but from the viewpoint of the effect of the present invention, the shape may be the one that can be regarded as a polygon (substantial polygon), for example, an m-polygon partly having irregularities, or an m-polygon having at least one rounded corner.

An embodiment of the present invention has been described above. All the matters described can be applied to all the aspects of the present invention.

The present invention will be described in more detail with reference to examples and comparative examples, but the present invention is not limited to only these examples.

### Example 1

A liquid crystal display device according to Example 1 is a specific example of the liquid crystal display device 100A according to Embodiment 1 described above and has the following configuration.

A pixel pitch in the liquid crystal display device 100A was 7.0 μm×21.0 μm (1210 ppi), and a plate-shaped pixel electrode 12 having no punched shape such as an opening was provided on an insulating substrate 11. A counter electrode 14 provided with an opening portion 15 having a longitudinal shape shown in FIG. 2 was disposed through an insulating film 13 with dielectric constant ε=6.9. Assuming that the azimuth direction of the opening portion 15 in a certain unit of display 50 was 83°, the opening portions 15 were set such that the opening portions 15 in the four units of display 50, i.e., the upper, lower, left, and right units of display 50 that were in contact with each other, each had an azimuth direction of 97°. Further, the width of the opening portion 15 was S=2.0 μm. Note that the opening portion 15 provided in the counter electrode 14 used in Example 1 is an opening portion having a longitudinal shape having a longitudinal direction 15A and a transverse direction 15B, and the azimuth direction of the opening portion 15 is the angle of the longitudinal direction 15A of the opening portion 15 with reference to the polarization axis shown in FIG. 2.

A liquid crystal layer 20 was provided on the counter electrode 14 through an alignment film (not shown). The refractive index anisotropy (Δn) of the liquid crystal layer 20 was set to 0.111, and the in-plane retardation (Re) was set to 330 nm. The viscosity and anisotropy of dielectric constant (Δε) of the liquid crystal molecules 21 used for the liquid crystal layer 20 were respectively set to 70 cps and 7 (positive type).

In a voltage non-applied state in which no voltage was applied between the pixel electrode 12 and the counter electrode 14, liquid crystal molecules 21 were set in horizontal alignment so as to be aligned parallel to the first substrate 10, and an initial alignment azimuth direction 22 of the liquid crystal molecules 21 was set to be parallel to straight lines respectively having angles of 90° and 270° with respect to the polarization axis shown in FIG. 2. The polarizing plate was in a so-called normally black mode in which black display was performed in a voltage non-applied state (OFF state) with respect to the liquid crystal layer 20.

With respect to the liquid crystal display device 100A according to Example 1, the average slopes of the contours of the respective opening portions 15 in the four units of display 50 adjacent to each other vertically and laterally were obtained in the following manner, with the longitudinal direction of the unit of display 50 being the vertical direction, and the transverse direction being the lateral direction.

A straight line whose length (dividing length) is longest among straight lines dividing the opening portion 15 in the direction parallel to a source signal line 42 was defined as a first straight line, a straight line whose length (dividing length) is longest among straight lines dividing the opening portion 15 in the direction orthogonal to the first straight line was defined as a second straight line, and the longer of the first and second straight lines was defined as a reference line 15L of the opening portion 15. Then, the reference line 15L of the opening portion 15 was defined as the x-axis, and one of the first straight line and the second straight line which did not correspond to the reference line 15L of the opening portion 15 was defined as the y-axis. The contour of the opening portion 15 was projected on the x-axis, and 201 straight lines parallel to the y-axis were drawn, which divided the length into 200 equal parts. That is, 201 straight lines parallel to the y-axis were drawn, which equally divided the width of the contour of the opening portion 15 into 200 parts in the x-axis direction. At this time, a straight line parallel to the y-axis was drawn also on the two furthest points in the x-axis direction of the opening portion 15. Then, the slope at each intersection point was obtained by differentiating at the intersection points of all of these straight lines and the contour of the opening portion 15 (when there are a plurality of intersection points on one straight line, all intersection points). The value obtained by dividing the sum of the slopes by the total number of intersection points was taken as the average slope of the contour of the opening portion 15. Note that the point where the slope became 0 or infinite did not contribute to alignment control and hence was excluded.

Table 1 below shows the average slopes of the contours of the respective opening portions 15 in the four units of display 50 adjacent to each other vertically and horizontally in the liquid crystal display device 100A according to Example 1. Note that four units of display 50 adjacent to each other vertically and horizontally are sometimes expressed as the upper right unit of display 50, the upper left unit of display 50, the lower left unit of display 50, and the lower right unit of display 50.

In the four units of display 50 adjacent to each other vertically and horizontally, the upper right unit of display 50 is adjacent to the upper left and lower right units of display 50, and the upper left unit of display 50 is adjacent to the upper right and lower left units of display 50, the lower left unit of display 50 is adjacent to the upper left and lower right units of display 50, and the lower right unit of display 50 is adjacent to the lower left and upper right units of display 50. The upper right and lower left units of display 50 are diagonally related and not adjacent to each other, and the upper left and lower right units of display 50 are diagonally related and not adjacent to each other.

TABLE 1

| | Average slope of contour of opening portion | | | |
|---|---|---|---|---|
| | Upper right | Upper left | Lower left | Lower right |
| | unit of | unit of | unit of | unit of |
| | display | display | display | display |
| Example 1 | 0.12 | −0.12 | 0.12 | −0.12 |

According to Table 1, the average slope of the contour of the opening portion 15 in each unit of display 50 was not zero, and the sign of the average slope differed from the signs of the average slopes of the contours of the opening portions 15 in the adjacent units of display 50.

### Comparative Examples 1 and 2

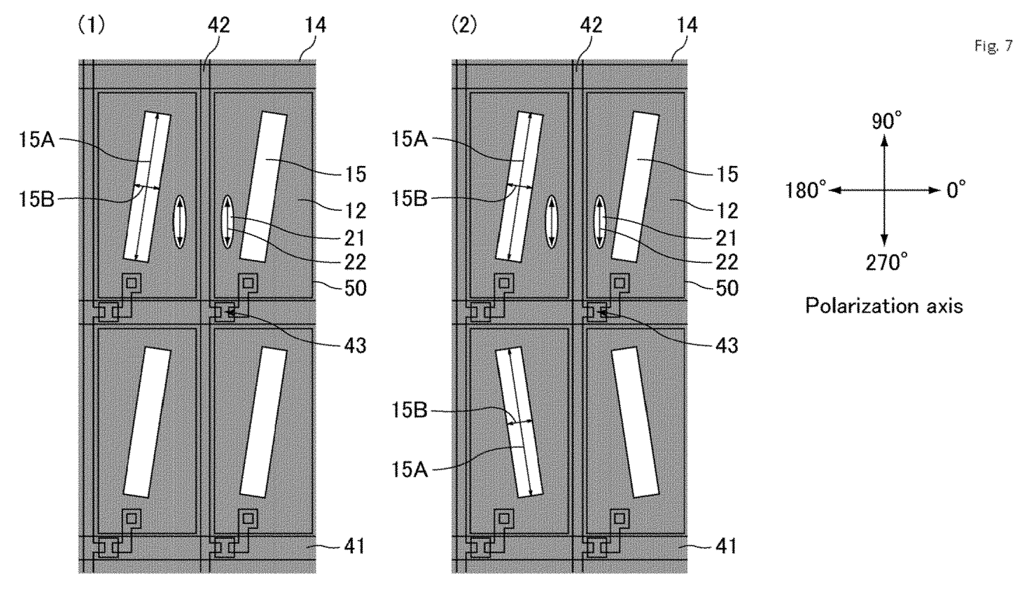

FIG. 7 is a schematic plan view of a liquid crystal display device according to a comparative example, with (1) being a schematic plan view of Comparative Example 1, and (2) being a schematic plan view of Comparative Example 2. Liquid crystal display devices 100A according to Comparative Examples 1 and 2 each have the same configuration as that of the liquid crystal display device 100A according to Example 1 except that the azimuth direction of an opening portion 15 of a counter electrode 14 was changed. As shown in FIG. 7(1), the azimuth direction of each opening portion 15 of the counter electrode 14 according to Comparative Example 1 was arranged so as to be 83° in all units of display 50. As shown in FIG. 7(2), in Comparative Example 2, the azimuth directions of all the opening portions 15 of the counter electrodes 14 on a given row (an array parallel to the extending direction of a gate signal lines 41) were set to 83°, and the azimuth directions of all the opening portions 15 of the counter electrodes 14 on upper and lower rows were set to 97°.

Note that the opening portion 15 provided in the counter electrode 14 used in each of Comparative Examples 1 and 2 is an opening portion having a longitudinal shape having a longitudinal direction 15A and a transverse direction 15B, and the azimuth direction of the opening portion 15 is the angle of the longitudinal direction 15A of the opening portion 15 with reference to the polarization axis shown in FIG. 7, like the opening portion 15 used in Example 1.

The average slope of the contour of the opening portion 15 used in each of Comparative Examples 1 and 2 was obtained in the same manner as in Example 1. Table 2 below shows the average slopes of the respective opening portions 15 in the four units of display 50 adjacent to each other vertically and horizontally in the liquid crystal display device 100A according to each of Comparative Examples 1 and 2.

TABLE 2

| | Average slope of contour of opening portion | | | |
|---|---|---|---|---|
| | Upper right | Upper left | Lower left | Lower right |
| | unit of | unit of | unit of | unit of |
| | display | display | display | display |
| Comparative | −0.12 | −0.12 | −0.12 | −0.12 |
| Example 1 | | | | |
| Comparative | −0.12 | −0.12 | 0.12 | 0.12 |
| Example 2 | | | | |

From Table 2, in Comparative Examples 1 and 2, although the average slope of the contour of the opening portion 15 in each unit of display 50 was not zero, the sign of the average slope of the contour of the opening portion 15 in each unit of display 50 was the same as the signs of the average slopes of the contours of the opening portions 15 in the vertically and/or horizontally adjacent units of display 50.

### Comparison Between Example 1 and Comparative Examples 1 and 2

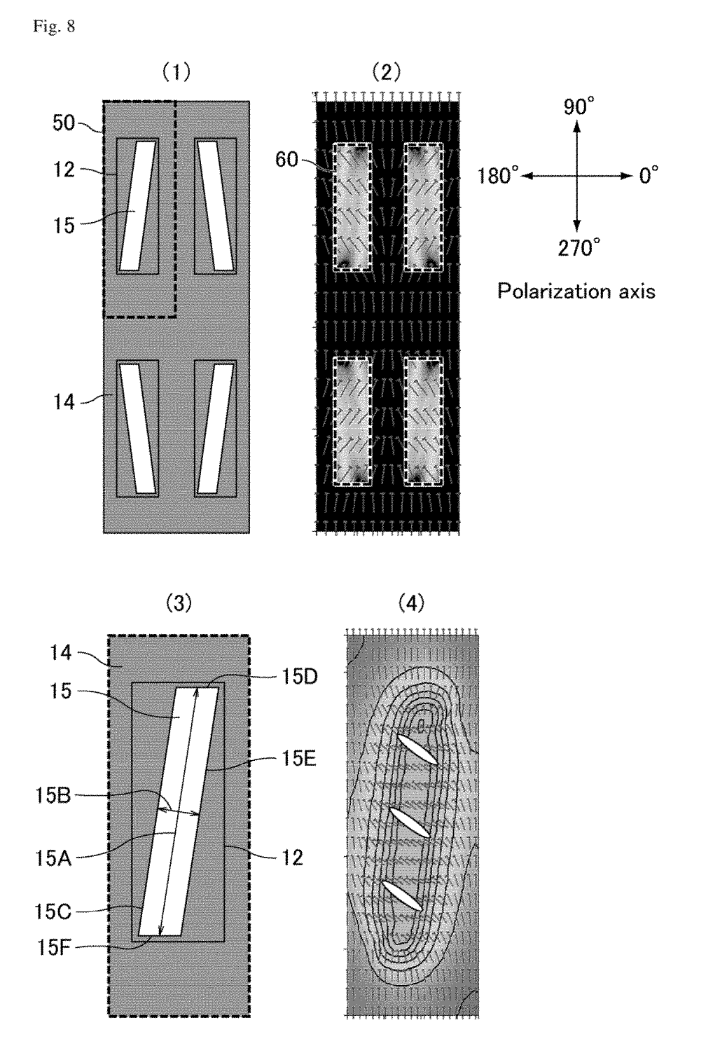

The alignment distribution of the liquid crystal molecules 21 in the ON state (upon application of a voltage of 4.5 V) of each of the liquid crystal display devices 100A according to Example 1 and Comparative Examples 1 and 2 will be described with reference to FIGS. 8 to 10.

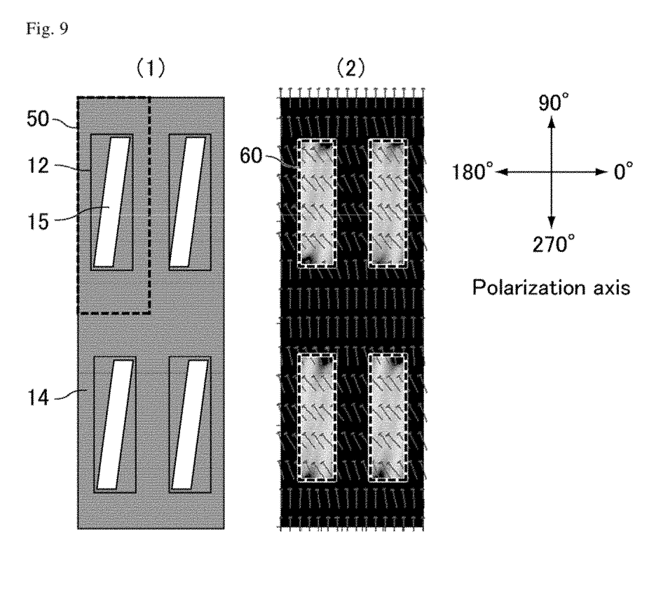

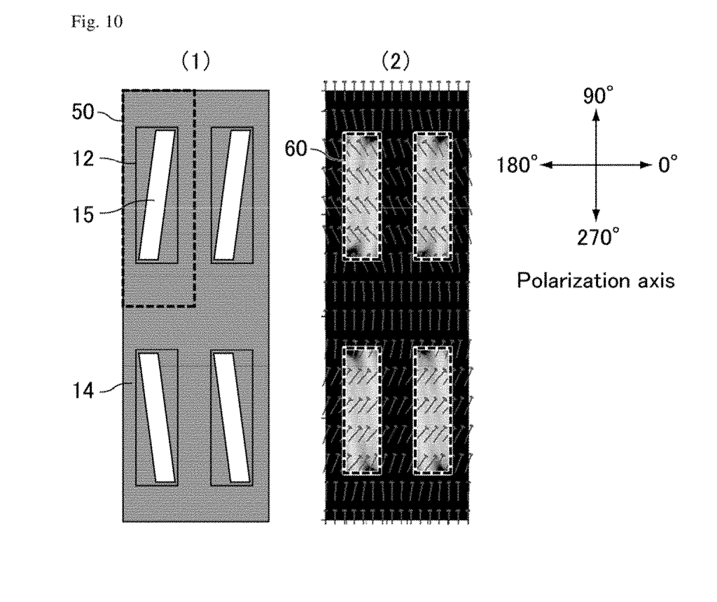

FIGS. 8(1), 9(1), and 10(1) are schematic plan views showing counter electrodes and pixel electrodes according to Example 1 and Comparative Examples 1 and 2, and FIGS. 8(2), 9(2), and 10(2) are plan views showing the alignment distribution simulation results of liquid crystal molecules when 4.5 V is applied to the liquid crystal display devices according to Example 1 and Comparative Examples 1 and 2. FIG. 8(3) is a schematic plan view showing a counter electrode and pixel electrodes according to Example 1, and FIG. 8(4) is a view showing an electric field distribution in the region in (3) at the time of voltage application. FIGS. 8(1) and (2), FIGS. 9(1) and 9(2), and FIGS. 10(1) and 10(2) are views showing four units of display, and FIGS. 8(3) and 8(4) are views showing one unit of display. LCD-Master 3D available from Shintech Co., Ltd. was used for simulation in each example and each comparative example.

According to the simulation result of FIG. 8(2), in the liquid crystal display device 100A according to Example 1, the liquid crystal molecules 21 rotate in opposite azimuth directions in the display regions 60 of the units of display 50 adjacent to each other vertically and horizontally, and four liquid crystal domains are formed. In addition, bend-shaped or splay-shaped liquid crystal alignment occurs between two adjacent liquid crystal domains. On the other hand, in the liquid crystal display device 100A according to Comparative Example 1, the simulation result of FIG. 9(2) indicates that the liquid crystal molecules 21 rotate in one azimuth direction in the display region 60 of all the units of display 50. In addition, in the liquid crystal display device 100A according to Comparative Example 2, the simulation result of FIG. 10(2) indicates that the liquid crystal molecules 21 rotate in two azimuth directions while changing the azimuth direction for each row.

With respect to Example 1, the fringe electric field generated between the pixel electrode 12 and the counter electrode 14 was studied. As shown in FIGS. 8(3) and 8(4), the opening portion 15 used in Example 1 has a shape formed by four contour portions 15C to 15F, which is a rectangle constituted by a pair of long sides (15C and 15E) and a pair of short sides (15D and 15F). In this case, the contour portions 15C and 15E face a desired azimuth direction, but the contour portions 15C and 15E do not face a desired azimuth direction. More specifically, at the contour portions 15C and 15E, a fringe electric field is generated to rotate the liquid crystal molecules 21 in an azimuth direction of 90° to 180° of the polarization axis which is a desired azimuth direction. At the contour portions 15D and 15F, a fringe electric field is generated to rotate the liquid crystal molecules 21 in an azimuth direction other than the azimuth direction described above. However, the contour portions 15C and 15E are longer than the contour portions 15D and 15F. Therefore, the average slope of the contour portions 15C to 15F corresponds to a desired azimuth direction, and the liquid crystal molecules 21 rotate in an azimuth direction substantially equal to the desired azimuth direction (an azimuth direction of 90° to 180° of the polarization axis).

With respect to each of the liquid crystal display devices 100A according to Example 1 and Comparative Examples 1 and 2, further simulation was carried out under the following evaluation conditions.

### Evaluation Conditions

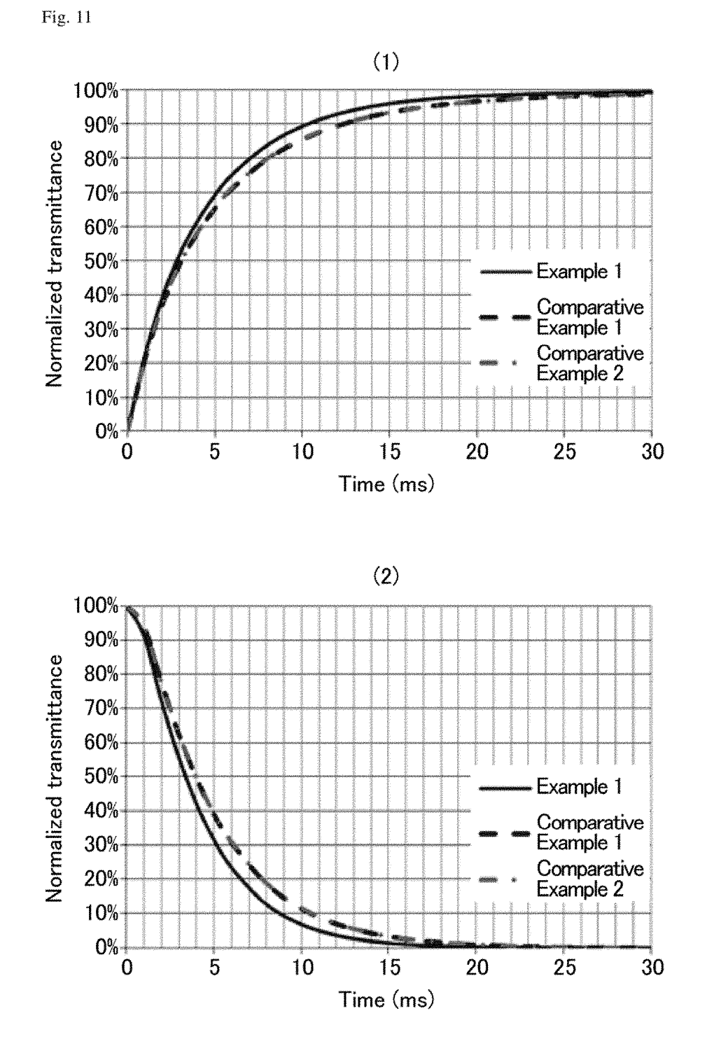

The maximum value of the transmittance obtained by optical modulation is defined as a transmittance ratio of 100%, the rise response time (τr) was the time required for the change from a transmittance ratio of 10% to a transmittance ratio of 90%. The decay response time (τd) was the time required for the change from a transmittance ratio of 90% to a transmittance ratio of 10%. The rise response characteristic corresponds to switching from black display to white display, and the decay response characteristic corresponds to switching from white display to black display. The results are shown in FIG. 11 and Table 3. FIG. 11 is a graph showing the response characteristics of the liquid crystal display devices according to Example 1 and Comparative Examples 1 and 2, with (1) being a graph showing a rise response characteristic, and (2) being a graph showing a decay response characteristic. Table 3 shows the rise response time (τr) and the decay response time (τd).

TABLE 3

| | | Comparative | Comparative |
|---|---|---|---|
| | Example 1 | Example 1 | Example 2 |
| _{τ}r (ms) | 6.5 | 7.5 | 7.5 |
| _{τ}d (ms) | 7.2 | 9.7 | 9.7 |
| _{τ}r + _{τ}d (ms) | 13.7 | 17.2 | 17.2 |

FIG. 11 and Table 3 indicate that the liquid crystal display device 100A according to Example 1 is faster than the liquid crystal display device 100A according to Comparative Examples 1 and 2 in both rise response and decay response. The reason why the liquid crystal display device 100A according to Example 1 is faster than Comparative Examples 1 and 2 is considered as follows.

When a voltage is applied between the pixel electrode 12 and the counter electrode 14, the liquid crystal molecules 21 rotate accompanying the generation of a fringe electric field, but because an electric field is weak at a point away from an edge portion (edge) of the opening portion 15, the rotation of the liquid crystal molecules 21 slows down, and the liquid crystal molecules 21 that slowly rotate become a factor that reduces the rise response speed of the liquid crystal display device 100A. In the liquid crystal display device 100A according to Comparative Examples 1 and 2, as indicated by the simulation results of FIGS. 9(2) and 10(2), in a plurality of units of display 50 arranged in a matrix, the liquid crystal molecules 21 in the display region 60 of the unit of display 50 adjacent in the transverse direction of the unit of display 50 (the row direction of the matrix) rotate in the same azimuth direction, and the liquid crystal molecules 21 at the point between the units of display 50 further away from the opening portion 15 also rotate. However, because the electric field is weak at this point, the rotation of the liquid crystal molecules 21 slow down. As a result, the rise response of the liquid crystal display device 100A slows down. On the other hand, in the liquid crystal display device according to Example 1, as indicated by the simulation result of FIG. 8(2), the liquid crystal molecules 21 in the display regions 60 of the adjacent units of display 50 rotate in opposite azimuth directions. The liquid crystal molecules 21 at points away from the opening portion 15 do not rotate or rotate with a small degree of rotation, and there are few liquid crystal molecules 21 that slowly rotate. For these reasons, it is considered that the rise response of the liquid crystal display device 100A according to Example 1 is faster than Comparative Examples 1 and 2.

In the liquid crystal display device 100A according to Example 1, the liquid crystal molecules 21 rotate in opposite azimuth directions in the display regions 60 of the adjacent units of display 50, and the alignment of the liquid crystal molecules 21 is deformed in a bend-shaped or splay-shape alignment in a horizontal plane between the units of display 50. It is considered that the distortion of the alignment of the liquid crystal molecules 21 due to such deformation becomes a restoring force for restoring the liquid crystal molecules 21 to the original alignment at the time of decay response and the decay response becomes faster. On the other hand, it is considered that in the liquid crystal display device 100A according to Comparative Examples 1 and 2, because the degree of occurrence of deformation into a bend shape and a splay shape in the horizontal plane is low, the restoring force for restoring the liquid crystal molecules 21 to the original alignment at the time of decay response is small, and the decay response is slow.

For the above reasons, both the rise response and the decay response in Example 1 are considered to be faster than in Comparative Examples 1 and 2.

In the liquid crystal display device 100A according to Example 1, compared with Comparative Examples 1 and 2, the region in which the liquid crystal molecules 21 rotate is small. However, the region (dark line) in which the liquid crystal molecules 21 do not rotate can be made to overlap the light-shielding region (the region where data line conductive lines and TFTs are present or a non-opening region) between the adjacent units of display 50, so that the transmittance of the opening portion 15 can be kept as high as that of Comparative Examples 1 and 2.

### Examples 2 to 5 and Comparative Examples 3 to 10

Liquid crystal display devices 100A according to Example 2 and Comparative Examples 3 and 4 each have the same configuration as that of each of the liquid crystal display devices 100A according to Example 1 and Comparative Examples 1 and 2 except that the pixel pitch was changed to 5.3 μm×15.9 μm (1597 ppi).

The liquid crystal display devices 100A according to Example 3 and Comparative Examples 5 and 6 each have the same configuration as that of each of the liquid crystal display devices 100A according to Example 1 and Comparative Examples 1 and 2 except that the pixel pitch was changed to 8.4 μm×25.2 μm (1008 ppi) and the width of the opening portion 15 was changed to width S=2.5 μm.

The liquid crystal display devices 100A according to Example 4 and Comparative Examples 7 and 8 each have the same configuration as that of each of the liquid crystal display devices 100A according to Example 1 and Comparative Examples 1 and 2 except that the pixel pitch was changed to 10.5 μm×31.5 μm (806 ppi) and the width of the opening portion 15 was changed to width S=3.0 μm.

The liquid crystal display devices 100A according to Example 5 and Comparative Examples 9 and 10 each have the same configuration as that of each of the liquid crystal display devices 100A according to Example 1 and Comparative Examples 1 and 2 except that the pixel pitch was changed to 14.0 μm×42.0 μm (605 ppi) and the width of the opening portion 15 was changed to width S=3.0 μm.

The average slope of the contour of the opening portion 15 used in each of Examples 2 to 5 and Comparative Examples 3 to 10 was obtained in the same manner as in Example 1. Table 4 below shows the average slopes of the respective opening portions 15 in the four units of display 50 adjacent to each other vertically and horizontally in the liquid crystal display device 100A according to each of Examples 2 to 5 and Comparative Examples 3 to 10.

TABLE 4

| | Average slope of contour of opening portion | | | |
|---|---|---|---|---|
| | Upper right | Upper left | Lower left | Lower right |
| | unit of | unit of | unit of | unit of |
| | display | display | display | display |
| Example 2 | 0.12 | −0.12 | 0.12 | −0.12 |
| Example 3 | 0.12 | −0.12 | 0.12 | −0.12 |
| Example 4 | 0.12 | −0.12 | 0.12 | −0.12 |
| Example 5 | 0.12 | −0.12 | 0.12 | −0.12 |
| Comparative | −0.12 | −0.12 | −0.12 | −0.12 |
| Example 3 | | | | |
| Comparative | −0.12 | −0.12 | 0.12 | 0.12 |
| Example 4 | | | | |
| Comparative | −0.12 | −0.12 | −0.12 | −0.12 |
| Example 5 | | | | |
| Comparative | −0.12 | −0.12 | 0.12 | 0.12 |
| Example 6 | | | | |
| Comparative | −0.12 | −0.12 | −0.12 | −0.12 |
| Example 7 | | | | |
| Comparative | −0.12 | −0.12 | 0.12 | 0.12 |
| Example 8 | | | | |
| Comparative | −0.12 | −0.12 | −0.12 | −0.12 |
| Example 9 | | | | |
| Comparative | −0.12 | −0.12 | 0.12 | 0.12 |
| Example 10 | | | | |

According to Table 4, in each of Examples 2 to 5, the average slope of the contour of the opening portion 15 in each unit of display 50 was not zero, and the sign of the average slope differed from the signs of the average slopes of the contours of the opening portions 15 in the adjacent units of display 50. On the other hand, in Comparative Examples 3 to 10, although the average slope of the contour of the opening portion 15 in each unit of display 50 was not zero, the sign of the average slope of the contour of the opening portion 15 in each unit of display 50 was the same as the signs of the average slopes of the contours of the opening portions 15 in the vertically and/or horizontally adjacent units of display 50.

### Comparisons Between Examples 2 to 5 and Comparative Examples 3 to 10

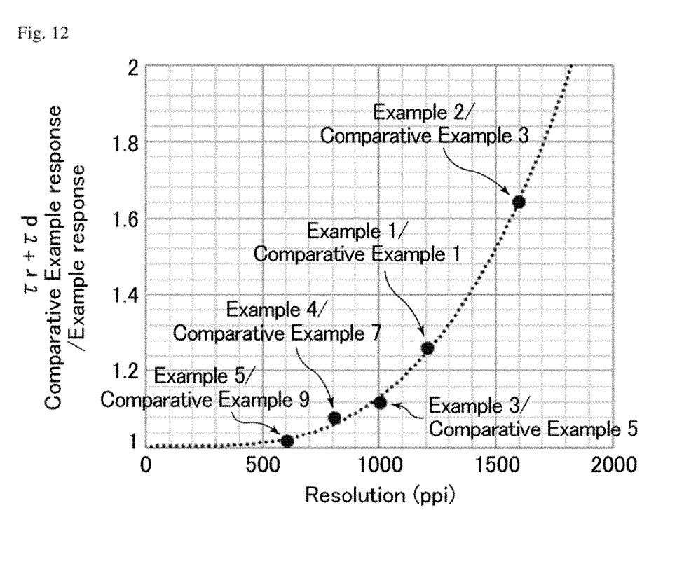

Simulation concerning the rise response time (τr) and the decay response time (τd) was carried out for each of the liquid crystal display devices 100A according to Examples 2 to 5 and Comparative Examples 3 to 10 using the same evaluation conditions as in Example 1 and the like. The results are shown in Table 5 and FIG. 12. Table 5 summarizes the rise response times (τr) and the decay response times (τd) concerning the liquid crystal display devices 100A according to Examples 1 to 5 and Comparative Examples 1 to 10. FIG. 12 is a graph obtained by plotting the response time ratios between the liquid crystal display devices according to Examples 1 to 5 and Comparative Examples 1, 3, 5, 7, and 9 as a function of resolution.

TABLE 5

| | | | | | | _{τ}r + _{τ}d |
|---|---|---|---|---|---|---|
| | | | | | | Comparative |
| | | | | | | Example/ |
| Resolution | | | _{τ}r (ms) | _{τ}d (ms) | _{τ}r + _{τ}d (ms) | Example |
| 1597 | ppi | Example 2 | 7.1 | 5.4 | 12.5 | 1.64 |
| | | Comparative | 11.5 | 9.0 | 20.5 | |
| | | Example 3 | | | | |
| | | Comparative | 11.5 | 9.0 | 20.5 | |
| | | Example 4 | | | | |
| 1210 | ppi | Example 1 | 6.5 | 7.2 | 13.7 | 1.26 |
| | | Comparative | 7.5 | 9.7 | 17.2 | |
| | | Example 1 | | | | |
| | | Comparative | 7.5 | 9.7 | 17.2 | |
| | | Example 2 | | | | |
| 1008 | ppi | Example 3 | 9.5 | 8.5 | 18.0 | 1.12 |
| | | Comparative | 10.4 | 9.8 | 20.2 | |
| | | Example 5 | | | | |
| | | Comparative | 10.4 | 9.8 | 20.2 | |
| | | Example 6 | | | | |
| 806 | ppi | Example 4 | 9.1 | 9.8 | 18.9 | 1.08 |
| | | Comparative | 9.8 | 10.6 | 20.4 | |
| | | Example 7 | | | | |
| | | Comparative | 9.8 | 10.6 | 20.4 | |
| | | Example 8 | | | | |
| 605 | ppi | Example 5 | 12.8 | 9.5 | 22.3 | 1.02 |
| | | Comparative | 13.0 | 9.7 | 22.7 | |
| | | Example 9 | | | | |
| | | Comparative | 13.0 | 9.7 | 22.7 | |
| | | Example 10 | | | | |

Table 5 indicates that both the rise response time and the decay response time in the examples were faster than in the comparative examples at any resolution.

The sum (τr+τd) of the rise response time and the decay response time was calculated, and the result obtained in each comparative example was divided by the result obtained in a corresponding one of the examples at the same resolution. FIG. 12 shows a plot of the calculation results as a function of resolution. FIG. 12 indicates that as the resolution increases, the responsiveness of the liquid crystal display device according to each example becomes significantly higher. From this result, the resolution of the liquid crystal display device 100A is preferably 600 ppi or more, more preferably 800 ppi or more, and still more preferably 1000 ppi or more.

### Example 6

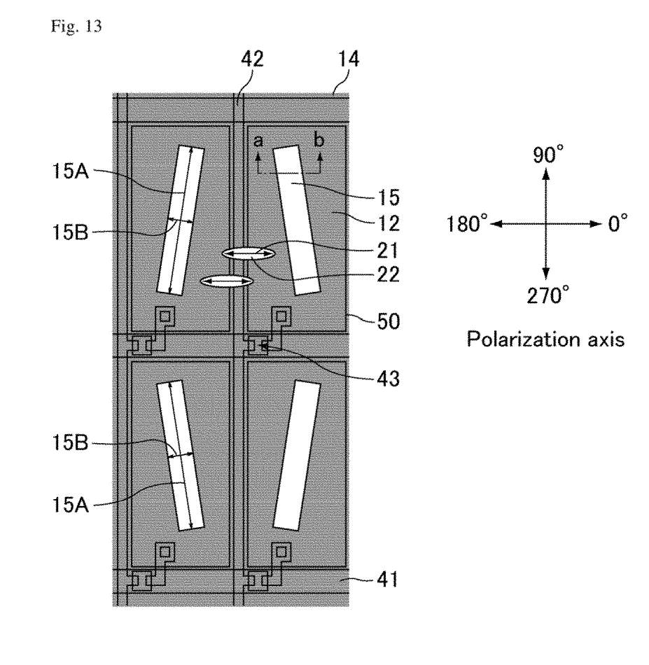

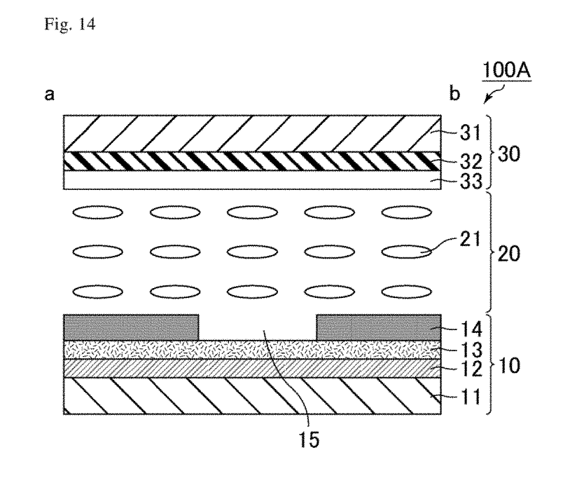

FIGS. 13 and 14 show the basic configuration of Example 6. FIG. 13 is a schematic plan view of a liquid crystal display device according to Example 6. FIG. 14 is a schematic cross-sectional view of the liquid crystal display device according to Example 6, showing an OFF state. A liquid crystal display device 100A according to Example 6 has the same configuration as that of the liquid crystal display device 100A according to Example 1 except that the liquid crystal molecules 21 and the initial alignment azimuth direction 22 of the liquid crystal molecules 21 were changed.

In the liquid crystal display device 100A according to Example 6, the liquid crystal molecules 21 having a viscosity of 96 cps and anisotropy of dielectric constant (Δε) of −2.5 (negative type) were used for a liquid crystal layer 20, and the liquid crystal layer 20 having a refractive index anisotropy (Δn) of 0.107 and an in-plane retardation (Re) of 320 nm was disposed on a counter electrode 14 through an alignment film (not shown). The liquid crystal molecules 21 were aligned (horizontally aligned) such that the liquid crystal molecules 21 were parallel to the first substrate 10 in the voltage non-applied state and the longitudinal direction of the liquid crystal molecules 21 was parallel to the transverse direction of a unit of display 50 (that is, the initial alignment azimuth direction 22 of the liquid crystal molecules 21 was parallel to a straight line connecting 0° and 180° on the polarization axis).

The average slope of the contour of the opening portion 15 used in Example 6 was obtained in the same manner as in Example 1. Table 6 below shows the average slopes of the respective opening portions 15 in the four units of display 50 adjacent to each other vertically and horizontally in the liquid crystal display device 100A according to Example 6.

TABLE 6

| | Average slope of contour of opening portion | | | |
|---|---|---|---|---|
| | Upper right | Upper left | Lower left | Lower right |
| | unit of | unit of | unit of | unit of |
| | display | display | display | display |
| Example 6 | 0.12 | −0.12 | 0.12 | −0.12 |

According to Table 6, the average slope of the contour of the opening portion 15 in each unit of display 50 was not zero, and the sign of the average slop differed from the signs of the average slopes of the contours of the opening portions 15 in the adjacent units of display 50.

### Comparative Examples 11 and 12

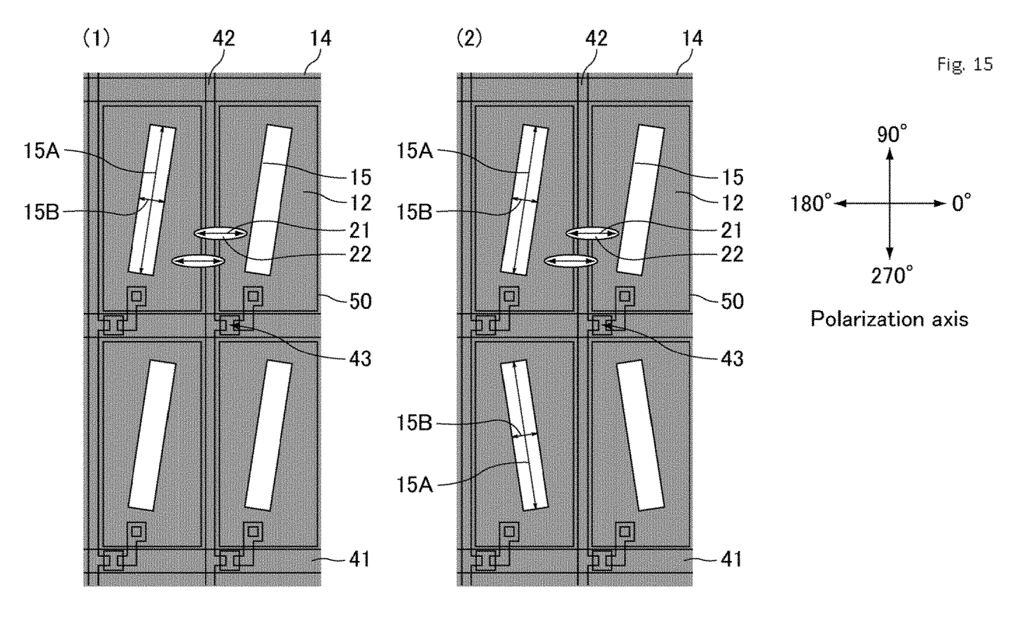

FIG. 15 is a schematic plan view of a liquid crystal display device according to a comparative example, with (1) being a schematic plan view of Comparative Example 11, and (2) being a schematic plan view of Comparative Example 12. Liquid crystal display devices 100A according to Comparative Examples 11 and 12 each have the same configuration as that of the liquid crystal display device 100A according to Example 6 except that the azimuth direction of an opening portion 15 of a counter electrode 14 was changed. As shown in FIG. 15(1), the azimuth direction of each opening portion 15 according to Comparative Example 11 was arranged so as to be 83° in all the units of display 50. As shown in FIG. 15(2), in Comparative Example 12, the azimuth directions of all the opening portions 15 on a given row were set to 83°, and the azimuth directions of all the opening portions 15 on the upper and lower rows were set to 97°.

The average slope of the contour of the opening portion 15 used in each of Examples 11 and 12 was obtained in the same manner as in Example 1. Table 7 below shows the average slopes of the respective opening portions 15 in the four units of display 50 adjacent to each other vertically and horizontally in the liquid crystal display device 100A according to each of Comparative Examples 11 and 12.

TABLE 7

| | Average slope of contour of opening portion | | | |
|---|---|---|---|---|
| | Upper right | Upper left | Lower left | Lower right |
| | unit of | unit of | unit of | unit of |
| | display | display | display | display |
| Comparative | −0.12 | −0.12 | −0.12 | −0.12 |
| Example 11 | | | | |
| Comparative | −0.12 | −0.12 | 0.12 | 0.12 |
| Example 12 | | | | |

From Table 7, in Comparative Examples 11 and 12, although the average slope of the contour of the opening portion 15 in each unit of display 50 was not zero, the sign of the average slope of the contour of the opening portion 15 in each unit of display 50 is the same as the signs of the average slopes of the contours of the opening portions 15 in the vertically and/or horizontally adjacent units of display 50.

### Comparisons Between Example 6 and Comparative Examples 11 and 12

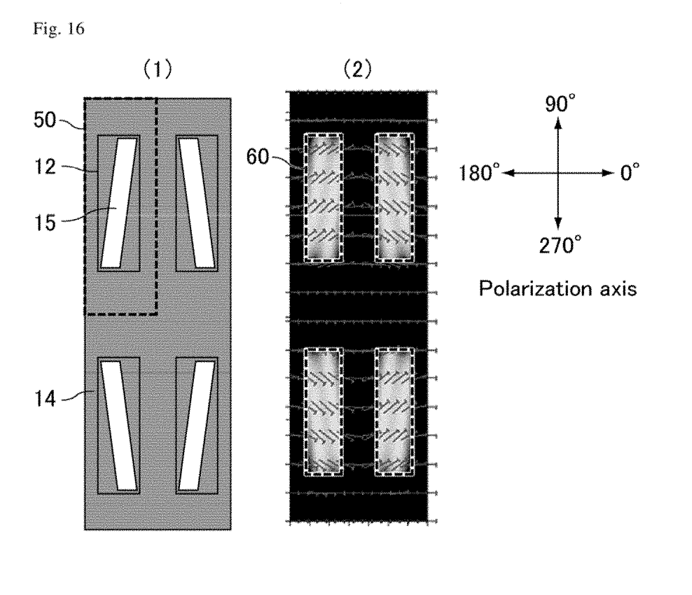

The alignment distribution of the liquid crystal molecules 21 in the ON state (upon application of a voltage of 6.0 V) of each of the liquid crystal display devices 100A according to Example 6 and Comparative Examples 11 and 12 will be described with reference to FIGS. 16 to 18.

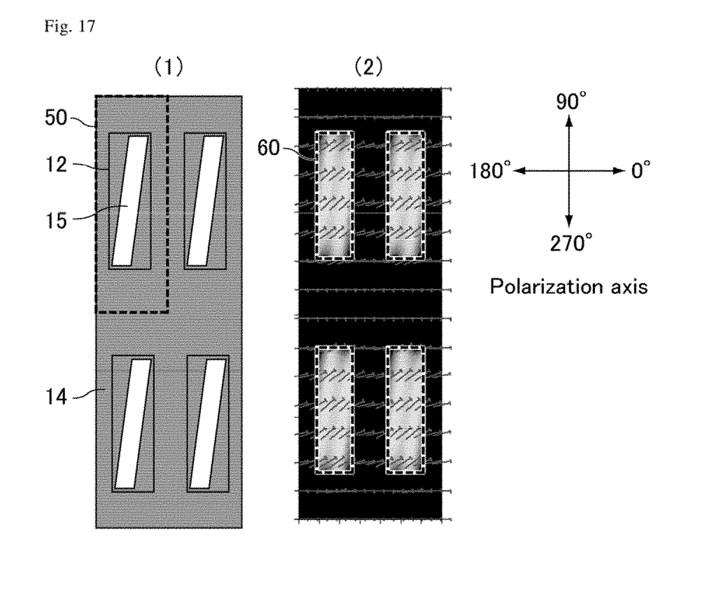

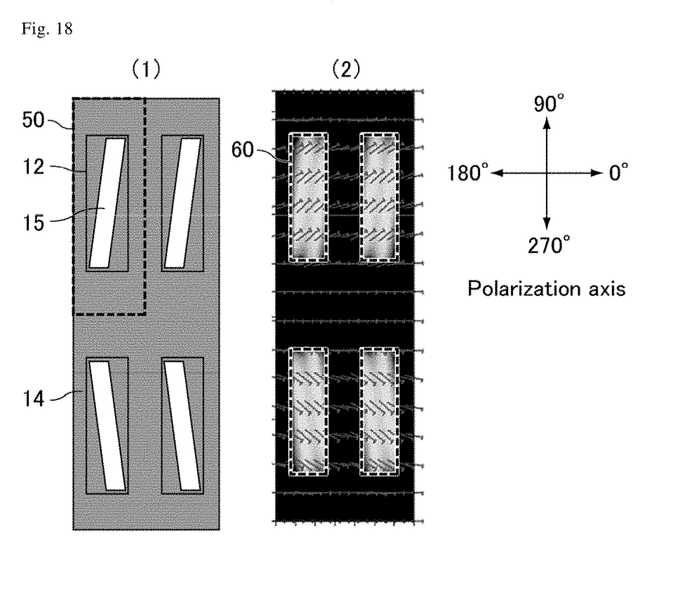

FIG. 16(1), FIG. 17(1), and FIG. 18(1) are schematic plan views showing counter electrodes and pixel electrodes according to Example 6 and Comparative Examples 11 and 12, respectively. FIGS. 16(2), 17(2), and 18(2) are plan views showing the alignment distribution simulation results of the liquid crystal molecules upon application of a voltage of 6.0 V in the liquid crystal display devices according to Example 6 and Comparative Examples 11 and 12.

As indicated by the simulation result of FIG. 16(2), in the liquid crystal display device 100A according to Example 6, the liquid crystal molecules 21 rotate in opposite azimuth directions in the display regions 60 of the units of display 50 adjacent to each other vertically and horizontally, and four liquid crystal domains are formed. In addition, bend-shaped or splay-shaped liquid crystal alignment occurs between two adjacent liquid crystal domains. On the other hand, in the liquid crystal display device 100A according to Comparative Example 11, the simulation result in FIG. 17(2) indicates that the liquid crystal molecules 21 rotate in one azimuth direction in the display regions 60 of all the units of display 50. In addition, in the liquid crystal display device 100A according to Comparative Example 12, the simulation result of FIG. 18(2) indicates that the liquid crystal molecules 21 rotate in two azimuth directions while changing the azimuth direction for each row.

In Example 6, because the liquid crystal molecules 21 rotate in opposite azimuth directions in the display regions 60 of the units of display 50 adjacent to each other vertically and horizontally, high-speed response can be achieved for the same reason as in Example 1 and Comparative Examples 1 and 2 using a positive liquid crystal as compared with Comparative Example 11 in which the liquid crystal molecules 21 rotate only in one azimuth direction and Comparative Example 12 in which the liquid crystal molecules 21 rotate in only two azimuth directions.

Simulation concerning the rise response time (τr) and the decay response time (τd) was actually carried out for each of the liquid crystal display devices 100A according to Example 6 and Comparative Examples 11 and 12 using the same evaluation conditions as in Example 1 and the like. The results are shown in Table 8.

TABLE 8

| | | Comparative | Comparative |
|---|---|---|---|
| | Example 6 | Example 11 | Example 12 |
| _{τ}r (ms) | 9.9 | 10.7 | 10.7 |
| _{τ}d (ms) | 6.8 | 7.2 | 7.2 |
| _{τ}r + _{τ}d (ms) | 16.7 | 17.9 | 17.9 |

Table 8 indicates that the liquid crystal display device 100A according to Example 6 is faster than the liquid crystal display device 100A according to Comparative Examples 11 and 12 in both rise response and decay response.

In the liquid crystal display device 100A according to Example 6, compared with Comparative Examples 11 and 12, the region in which the liquid crystal molecules 21 rotate is small. However, the region (dark line) in which the liquid crystal molecules 21 do not rotate can be made to overlap the light-shielding region (the region where data line conductive lines and TFTs are present or a non-opening region) between the units of display 50, so that the transmittance of the opening portion 15 can be kept as high as that of Comparative Examples 11 and 12.

### Examples 7 and 8

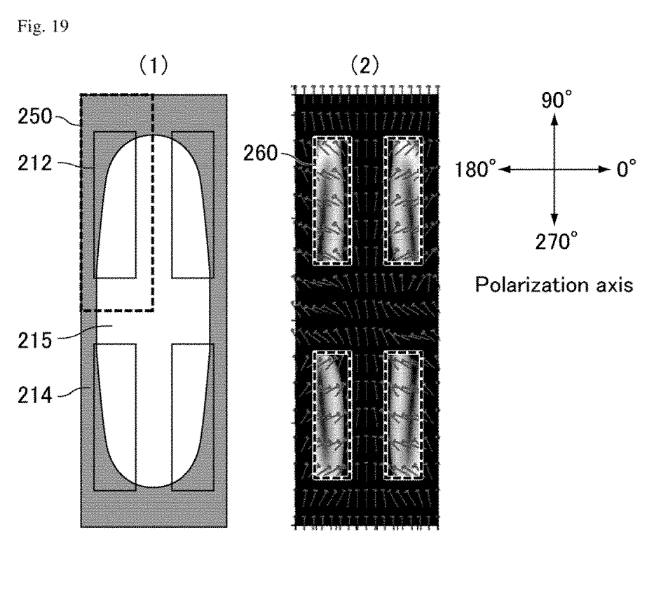

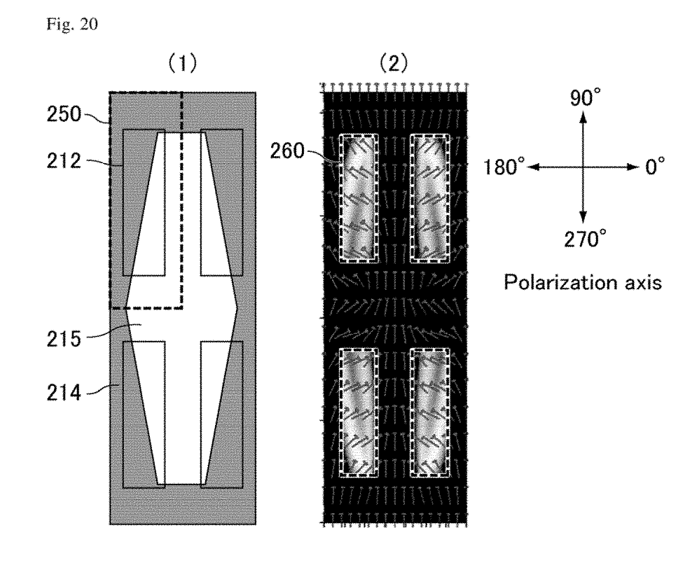

FIG. 19 is a view relating to a liquid crystal display device according to Example 7, with (1) being a schematic plan view showing a counter electrode and pixel electrodes, and (2) being a plan view showing alignment distribution simulation result of liquid crystal molecules upon application of a voltage of 4.5 V. FIG. 20 is a view relating to a liquid crystal display device according to Example 8, with (1) being a schematic plan view showing a counter electrode and pixel electrodes, and (2) being a plan view showing alignment distribution simulation result of liquid crystal molecules upon application of a voltage of 4.5 V. The liquid crystal display devices according to Examples 7 and 8 each have the same configuration as that of the liquid crystal display device 100A according to Example 1 except that the shape of an opening portion 15 was changed.

In a counter electrode 214 according to Example 7, as shown in FIG. 19(1), opening portions 215 in four units of display 250 adjacent to each other vertically and laterally form one elliptic shape. In a counter electrode 214 according to Example 8, as shown in FIG. 20(1), opening portions 215 in the four units of display 250 adjacent to each other vertically and laterally form one hexagonal shape.

The average slope of the contour of the opening portion 15 used in each of Examples 7 and 8 was obtained in the same manner as in Example 1. Table 9 below shows the average slopes of the respective opening portions 15 in the four units of display 250 adjacent to each other vertically and horizontally in a liquid crystal display device 200A according to each of Examples 7 and 8.

TABLE 9

| | Average slope of contour of opening portion | | | |
|---|---|---|---|---|
| | Upper right | Upper left | Lower left | Lower right |
| | unit of | unit of | unit of | unit of |
| | display | display | display | display |
| Example 7 | 0.29 | −0.29 | 0.29 | −0.29 |
| Example 8 | 0.16 | −0.16 | 0.16 | −0.16 |

According to Table 9, the average slope of the contour of the opening portion 215 in each unit of display 250 was not zero, and the sign of the average slope differed from the signs of the average slopes of the contours of the opening portions 215 in the adjacent units of display 250.

The alignment distribution of the liquid crystal molecules 221 in the ON state (upon application of a voltage of 4.5 V) of each of the liquid crystal display devices 200A according to Examples 7 and 8 will be described with reference to FIGS. 19 and 20.

As indicated by the simulation results of FIGS. 19(2) and 20(2), in each of the liquid crystal display devices 200A according to Examples 7 and 8, liquid crystal molecules 221 rotate in opposite azimuth directions in display regions 260 of the units of display 250 adjacent to each other vertically and horizontally, and four liquid crystal domains are formed. In addition, a bend-shaped or splay-shaped liquid crystal alignment occurred between two adjacent liquid crystal domains, and hence a higher speed can be achieved.

With respect to Example 7, the fringe electric field generated between the pixel electrode 212 and the counter electrode 214 was studied.

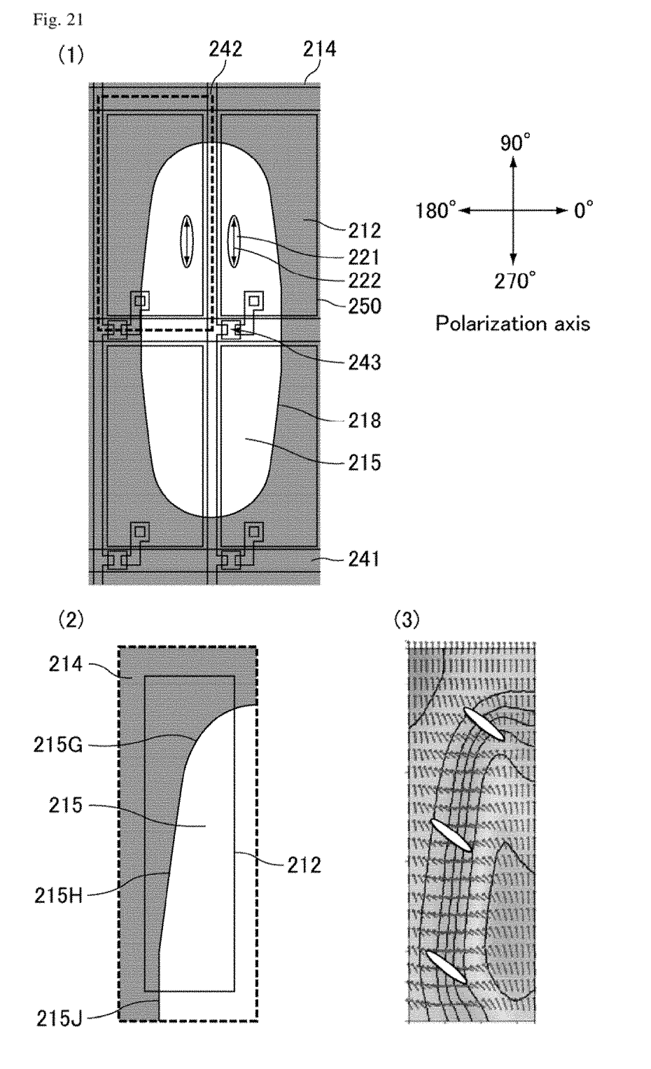

FIG. 21 is a view relating to a liquid crystal display device according to Example 7, with (1) being a schematic plan view of the liquid crystal display device, (2) being a schematic plan view showing a counter electrode and pixel electrodes, and (3) being a view showing an electric field distribution in the region in (2) at the time of voltage application.

As shown in FIGS. 21(2) and 21(3), the opening portion 215 is formed by an arcuate contour portion 215G, a linear contour portion 215H and a linear contour portion 215J. In this case, the contour portion 215G and the contour portion 215J face a desired direction, but the slope of the contour portion 215H is zero. More specifically, at the contour portions 215G and 215J of the opening portion 215, a fringe electric field that rotate the liquid crystal molecules 21 in an azimuth direction of 90° to 180° of the polarization axis which is a desired azimuth direction is generated. In contrast, at the contour portion 215H, because the contour portion 215H is parallel to the initial alignment azimuth direction 222 of the liquid crystal molecules 221 and the slope of the contour portion 215H is zero, no fringe electric field that rotates the liquid crystal molecules 221 is generated. Therefore, the average slopes of the contour portions 215G, 215H, and 215J correspond to a desired azimuth direction, and the liquid crystal molecules 221 rotate in an azimuth direction substantially equal to the desired azimuth direction (an azimuth direction of 90° to 180° of the polarization axis).

### Example 9

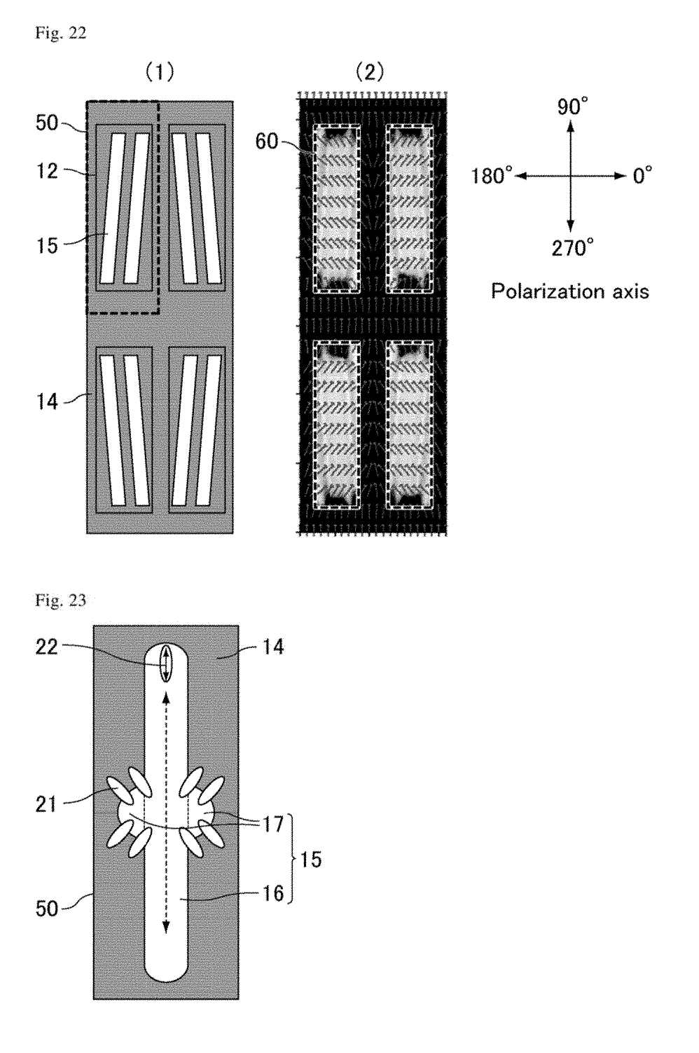

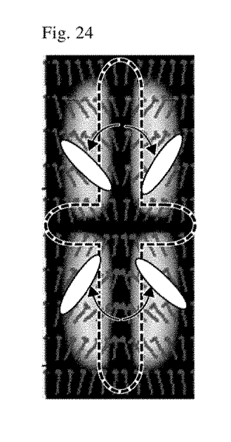

FIG. 22 is a view relating to a liquid crystal display device according to Example 9, with (1) being a schematic plan view showing a counter electrode and pixel electrodes, and (2) being a plan view showing the alignment distribution simulation result of liquid crystal molecules upon application of a voltage of 4.5 V. A liquid crystal display device 100A according to Example 9 has the same configuration as that of the liquid crystal display device 100A according to Example 4 except that an opening portion 15 was changed. In a counter electrode 14 according to Example 9, two slits having a width of 2.0 μm were arranged as opening portions 15 in parallel at an interval of 2.0 μm.

The average slope of the contour of the opening portion 15 used in Example 9 was obtained as follows. In Example 9, because two slits were formed for each unit of display 50, the average slope of the contour of each slit was calculated first in the same manner as in Example 1. Further, the average slope of the contour of the opening portion 15 in one unit of display 50 was obtained by dividing the sum of the average slopes by 2, which is the total number of slits. Table 10 below shows the average slopes of the respective opening portions 15 in the four units of display 50 adjacent to each other vertically and horizontally in the liquid crystal display device 100A according to Example 9.

TABLE 10

| | Average slope of contour of opening portion | | | |
|---|---|---|---|---|
| | Upper right | Upper left | Lower left | Lower right |
| | unit of | unit of | unit of | unit of |
| | display | display | display | display |
| Example 9 | 0.08 | −0.08 | 0.08 | −0.08 |

According to Table 10, the average slope of the contour of the opening portion 15 in each unit of display 50 was not zero, and the sign of the average slope differed from the signs of the average slopes of the contours of the opening portions 15 in the adjacent units of display 50.

The alignment distribution of the liquid crystal molecules 21 in the ON state (upon application of a voltage of 4.5 V) of the liquid crystal display device 100A according to Example 9 will be described with reference to FIG. 22.

As indicated by the simulation result of FIG. 22(2), in the liquid crystal display device 100A according to Example 9, the liquid crystal molecules 21 rotate in opposite azimuth directions in the display regions 60 of the units of display 50 adjacent to each other vertically and horizontally, and four liquid crystal domains are formed. In addition, a bend-shaped or splay-shaped liquid crystal alignment occurred between two adjacent liquid crystal domains, and hence a higher speed can be achieved.

### ADDITIONAL REMARKS

One aspect of the present invention may be a liquid crystal display device sequentially including: a first substrate; a liquid crystal layer containing liquid crystal molecules; and a second substrate, wherein the first substrate includes a first electrode, a second electrode provided closer to the liquid crystal layer than the first electrode is, and an insulating film provided between the first electrode and the second electrode, an opening portion is formed in the second electrode in each of a plurality of units of display arrayed in a matrix pattern, the liquid crystal molecules are aligned parallel to the first substrate in a voltage non-applied state in which no voltage is applied between the first electrode and the second electrode, and the average slope of the contour of the opening portion in each of the units of display is not zero, and the sign of the average slope differs from the signs of the average slopes of contours of opening portions in adjacent units of display.

According to this aspect, even when each opening of the electrode has a simple shape, it is possible to rotate the liquid crystal molecules in the same azimuth direction in the display region of one unit of display and to rotate the liquid crystal molecules in the display regions of the adjacent units of display in different azimuth directions. In addition, it is possible to form four liquid crystal domains whose liquid crystal molecules 21 are aligned symmetrically between four units of display and to make a crisscross dark line overlap a non-opening area between adjacent units of display. This can improve the response speed without reducing the transmittance even in a high-resolution liquid crystal display device.

The liquid crystal molecules may have positive anisotropy of dielectric constant.

The first substrate may further include a source signal line and a gate signal line, and an initial alignment azimuth direction of the liquid crystal molecules may be parallel to a reference line of the opening portion which is the longer of a first straight line and a second straight line, the first line being longest among lines dividing the opening portion in the direction parallel to the source signal line or the gate signal line, the second straight line being longest among lines dividing the opening portion in the direction orthogonal to the first straight line. According to this aspect, it is possible to further increase the transmittance.

The liquid crystal molecules may have negative anisotropy of dielectric constant.

The first substrate may further include a source signal line and a gate signal line, and an initial alignment azimuth direction of the liquid crystal molecules may be orthogonal to a reference line of the opening portion which is the longer of a first straight line and a second straight line, the first straight line being longest among lines dividing the opening portion in the direction parallel to the source signal line or the gate signal line, the second straight line being longest among lines dividing the opening portion in the direction orthogonal to the first straight line. According to this aspect, it is possible to further increase the transmittance.

A shape of the opening portion in each of the units of display may be mirror-symmetrical with a shape of the opening portion in each adjacent unit of display. According to this aspect, it is possible to achieve a desired alignment more efficiently.

In the second electrode, one or more slits may be formed as the opening portion for each of the units of display.

The opening portions in four display units adjacent to each other vertically and horizontally may form one shape.

The one shape may be an elliptic shape or oval shape. According to this aspect, it is possible to achieve a desired alignment more efficiently.

The one shape may be a polygonal shape. According to this aspect, it is possible to achieve a desired alignment more efficiently.

In a voltage applied state in which a voltage is applied between the first electrode and the second electrode, the liquid crystal molecules may be rotated in the same azimuth direction within a plane parallel to the first substrate in a display region of each of the units of display, and a rotational azimuth direction of the liquid crystal molecules in the display region of the unit of display may be opposite to a rotational azimuth direction of the liquid crystal molecules in a display region of each of the adjacent units of display. According to this aspect, it is possible to generate four liquid crystal domains in four units of display adjacent to each other vertically and horizontally and more reliably make the crisscross dark line overlap the non-opening region. This can further improve the transmittance.

### REFERENCE SIGNS LIST

10, 210 first substrate
11, 211 insulating substrate
12, 212 pixel electrode (first electrode)
13, 213 insulating layer (insulating film)
14, 214 counter electrode (second electrode)
15, 215 opening portion
15A longitudinal direction of opening
15B transverse direction of opening
15C, 15D, 15E, 15F, 215G, 215H, 215J contour portion of opening portion
15L reference line of opening portion
16 longitudinal portion
17 protruding portion
218 opening
20, 220 liquid crystal layer
21, 221 liquid crystal molecules
22, 222 initial alignment azimuth direction
30, 230 second substrate
31, 231 insulating substrate (for example, glass substrate)
32, 232 color filter
33, 233 overcoat layer
41, 241 gate signal line (scanning conductive line)
42, 242 source signal line (signal conductive line)
43, 243 TFT
50, 250 unit of display
60, 250 display region (opening area)

1. A liquid crystal display device sequentially comprising:
a first substrate;
a liquid crystal layer containing liquid crystal molecules; and
a second substrate,
wherein the first substrate includes a first electrode, a second electrode provided closer to the liquid crystal layer than the first electrode is, and an insulating film provided between the first electrode and the second electrode,
an opening portion is formed in the second electrode in each of a plurality of units of display arrayed in a matrix pattern,
the liquid crystal molecules are aligned parallel to the first substrate in a voltage non-applied state in which no voltage is applied between the first electrode and the second electrode, and
the average slope of the contour of the opening portion in each of the units of display is not zero, and the sign of the average slope differs from the signs of the average slopes of contours of opening portions in adjacent units of display.

2. The liquid crystal display device according to claim 1,
wherein the liquid crystal molecules have positive anisotropy of dielectric constant.

3. The liquid crystal display device according to claim 2,
wherein the first substrate further includes a source signal line and a gate signal line, and
an initial alignment azimuth direction of the liquid crystal molecules is parallel to a reference line of the opening portion which is the longer of a first straight line and a second straight line, the first line being longest among lines dividing the opening portion in the direction parallel to the source signal line or the gate signal line, the second straight line being longest among lines dividing the opening portion in the direction orthogonal to the first straight line.

4. The liquid crystal display device according to claim 1,
wherein the liquid crystal molecules have negative anisotropy of dielectric constant.

5. The liquid crystal display device according to claim 4,
wherein the first substrate further includes a source signal line and a gate signal line, and
an initial alignment azimuth direction of the liquid crystal molecules is orthogonal to a reference line of the opening portion which is the longer of a first straight line and a second straight line, the first straight line being longest among lines dividing the opening portion in the direction parallel to the source signal line or the gate signal line, the second straight line being longest among lines dividing the opening portion in the direction orthogonal to the first straight line.

6. The liquid crystal display device according to claim 1,
wherein a shape of the opening portion in each of the units of display is mirror-symmetrical with a shape of the opening portion in each adjacent unit of display.

7. The liquid crystal display device according to claim 1,
wherein in the second electrode, one or more slits are formed as the opening portion for each of the units of display.

8. The liquid crystal display device according to claim 1,
wherein the opening portions in four display units adjacent to each other vertically and horizontally form one shape.

9. The liquid crystal display device according to claim 8,
wherein the one shape is an elliptic shape or an oval shape.

10. The liquid crystal display device according to claim 8,
wherein the one shape is polygonal.

11. The liquid crystal display device according to claim 1,
wherein in a voltage applied state in which a voltage is applied between the first electrode and the second electrode, the liquid crystal molecules are rotated in the same azimuth direction within a plane parallel to the first substrate in a display region of each of the units of display, and a rotational azimuth direction of the liquid crystal molecules in the display region of the unit of display is opposite to a rotational azimuth direction of the liquid crystal molecules in a display region of each of the adjacent units of display.
